(19) United States
(12) Patent Application Publication
(10) Pub. No.: US 2025/0255064 A1
(43) Pub. Date: Aug. 7, 2025

(54) LIGHT EMITTING ELEMENT ARRAY, DISPLAY DEVICE INCLUDING THE LIGHT EMITTING ELEMENT ARRAY, AND METHOD OF MANUFACTURING THE LIGHT EMITTING ELEMENT ARRAY

(71) Applicant: Samsung Display Co., Ltd., Yongin-si (KR)

(72) Inventors: Woo Lim JEONG, Yongin-si (KR); Su Jeong KIM, Yongin-si (KR); Byung Ju LEE, Yongin-si (KR); Jeong Hun HEO, Yongin-si (KR); Jun Youn KIM, Yongin-si (KR)

(73) Assignee: Samsung Display Co., Ltd., Yongin-si (KR)

(21) Appl. No.: 18/883,565

(22) Filed: Sep. 12, 2024

(30) Foreign Application Priority Data
Feb. 6, 2024 (KR) 10-2024-0018460

(51) Int. Cl. H01L 27/15

(52) U.S. Cl. CPC H10H 29/142

(57) ABSTRACT

A light emitting element array includes light emitting elements on a substrate that emit different color lights. Each light emitting element includes a first semiconductor layer, a second semiconductor layer on the first semiconductor layer, doped with a first conductivity type, and containing indium, a light emitting layer on the second semiconductor layer and containing indium, and a third semiconductor layer on the light emitting layer and doped with a second conductivity type. An indium content of the light emitting layer of a first light emitting element among the light emitting elements is higher than an indium content of the light emitting layer of a second light emitting element among the light emitting elements. The second semiconductor layer of the first light emitting element includes first layers containing indium alternately stacked with second layers. The second semiconductor layer of the second light emitting element is a single layer containing indium.

### CROSS-REFERENCE TO RELATED APPLICATION(S)

This U.S. non-provisional patent application claims priority to and the benefits of Korean Patent Application No. 10-2024-0018460 under 35 U.S.C. § 119, filed in the Korean Patent Intellectual Property Office on Feb. 6, 2024, the entire contents of which are hereby incorporated by reference.

### BACKGROUND

### 1. Technical Field

Embodiments of the disclosure generally relate to a light emitting element array, a display device including the light emitting element array, and a method of manufacturing the light emitting element array.

### 2. Description of the Related Art

Light emitting elements are widely used as light sources of various electronic devices including display devices. For example, the light emitting elements are used as light sources of various electronic devices including virtual reality (VR) devices and augmented reality (AR) devices, as well as portable electronic devices and televisions.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

Some aspects are capable of providing a light emitting element array including light emitting elements that emit light of different colors.

Some aspects are capable of providing a display device including a light emitting element array including light emitting elements that emit light of different colors.

Some aspects are capable of providing a method of manufacturing a light emitting element array including light emitting elements that emit light of different colors.

Additional aspects will be set forth in the detailed description, which follows, and in part, will be apparent from the disclosure, or may be learned by practice of the disclosed embodiments and/or the claimed subject matter.

According to some embodiments, a light emitting element array includes a substrate and light emitting elements disposed on the substrate. The light emitting elements include a first light emitting element configured to emit a first color of light, and a second light emitting element configured to emit a second color of light different from the first color of light. Each of the light emitting elements includes a first semiconductor layer, a second semiconductor layer, a light emitting layer, and a third semiconductor layer. The second semiconductor layer is disposed on the first semiconductor layer, is doped to have a first conductivity type, and contains indium. The light emitting layer is disposed on the second semiconductor layer and contains indium. The third semiconductor layer is disposed on the light emitting layer and is doped to have a second conductivity type. An indium content of the light emitting layer of the first light emitting element is higher than an indium content of the light emitting layer of the second light emitting element. The second semiconductor layer of the first light emitting element is a multilayer structure. The multilayer structure includes first layers containing indium and second layers alternately stacked with the first layers. The second semiconductor layer of the second light emitting element is a single layer structure containing indium.

In an embodiment, each of the first layers of the first light emitting element may be an InGaN layer containing a dopant of the first conductivity type, and each of the second layers of the first light emitting element may be a GaN layer.

In an embodiment, the second semiconductor layer of the second light emitting element may be a single InGaN layer containing a dopant of the first conductivity type.

In an embodiment, a thickness of each of the first layers of the first light emitting element may be greater than a thickness of each of the second layers of the first light emitting element.

In an embodiment, the thickness of each of the first layers of the first light emitting element may be in a range of about 10 nm to about 20 nm.

In an embodiment, the thickness of each of the second layers of the first light emitting element may be less than or equal to about 5 nm and greater than 0 nm.

In an embodiment, an indium content of at least one of the first layers of the first light emitting element is different from an indium content of at least one other first layer among the first layers of the first light emitting element.

In an embodiment, the second semiconductor layer of the first light emitting element may include a first laminate, a second laminate, a third laminate, and a fourth laminate. The first laminate may include one or more first pairs of layers disposed on the first semiconductor layer. Each of the one or more first pairs of layers may include a first layer among the first layers and a second layer among the second layers. The second laminate may include one or more second pairs of layers disposed on the first laminate. Each of the one or more second pairs of layers may include a first layer among the first layers and a second layer among the second layers. The third laminate may include one or more third pairs of layers disposed on the second laminate. Each of the one or more third pairs of layers may include a first layer among the first layers and a second layer among the second layers. The fourth laminate may include one or more fourth pairs of layers disposed on the third laminate. Each of the one or more fourth pairs of layers may include a first layer among the first layers and a second layer among the second layers. An indium content of those first layers of the second laminate and an indium content of those first layers of the fourth laminate may be at least about 5% lower than an indium content of those first layers of the first laminate and an indium content of those first layers of the third laminate.

In an embodiment, both a number of the one or more first pairs of layers in the first laminate and a number of the one or more third pairs of layers in third laminate may be greater than both a number of the one or more second pairs of layers in the second laminate and a number of the one or more fourth pairs of layers in the fourth laminate.

In an embodiment, the light emitting layer of the first light emitting element may include a quantum well layer containing indium at a content in a range of about 30% to about 40%, and an indium content of at least one of the first layers of the first light emitting element may be less than or equal to about 30% and greater than 0%.

In an embodiment, a peak wavelength of the second color of light may be shorter than a peak wavelength of the first color of light.

In an embodiment, the light emitting elements may further include a third light emitting element configured to emit a third color of light. A peak wavelength of the third color of light may be shorter than the peak wavelength of the second color of light. The second semiconductor layer of the third light emitting element may be a single layer structure containing indium.

In an embodiment, the light emitting element array may further include an insulating layer disposed on a surface of the substrate. At least a portion of the insulating layer may be disposed between the first light emitting element and the second light emitting element in a view in a direction perpendicular to the surface.

In an embodiment, the insulating layer may overlap at least a portion of each of the light emitting elements. Each of the portions may include a peripheral side surface of a corresponding light emitting element among the light emitting elements.

In an embodiment, a thickness of the insulating layer overlapping the at least the portion of the first light emitting element may be different from a thickness of the insulating layer overlapping the at least the portion of the second light emitting element.

In an embodiment, the light emitting element array may further include a reflective layer disposed on the insulating layer. The reflective layer may overlap the peripheral side surfaces of the light emitting elements.

In an embodiment, at least parts of the first semiconductor layers of the light emitting elements may be integral with each other.

According to some embodiments, a display device includes a first pixel including a first light emitting element configured to emit a first color of light, and a second pixel including a second light emitting element configured to emit a second color of light. Each of the first light emitting element and the second light emitting element may include a first semiconductor layer, a second semiconductor layer, a light emitting layer, and a third semiconductor layer. The second semiconductor layer is disposed on a surface of the first semiconductor layer, is doped to have a first conductivity type, and contains indium. The light emitting layer is disposed on a surface of the second semiconductor layer and contains indium. The third semiconductor layer is disposed on a surface of the light emitting layer and is doped to have a second conductivity type. An indium content of the light emitting layer of the first light emitting element is higher than an indium content of the light emitting layer of the second light emitting element. The second semiconductor layer of the first light emitting element includes first layers containing indium and second layers alternately stacked with the first layers. The second semiconductor layer of the second light emitting element is a single layer structure containing indium.

According to some embodiments, a method of manufacturing a light emitting element array may include forming a first semiconductor layer on a surface of a substrate, and forming, on the first semiconductor layer, a first mask layer including a first opening exposing a first area of the first semiconductor layer, the first mask layer overlapping both a second area and a third area of the first semiconductor layer in a direction perpendicular to the surface. The method further includes sequentially forming, on the first area, a second semiconductor layer doped to have a first conductivity type and containing indium, a light emitting layer containing indium, and a third semiconductor layer doped to have a second conductivity type. The method further includes forming, on the first mask layer, a second mask layer including a second opening exposing the second area. The second mask layer overlaps both the first area and the second area in the direction. The method further includes sequentially forming, on the second area, a second semiconductor layer doped to have the first conductivity type and containing indium, a light emitting layer containing indium, and a third semiconductor layer doped to have the second conductivity type. The method further includes forming, on the second mask layer, a third mask layer including a third opening exposing the third area. The third mask layer overlapping both the first area and the second area in the direction. The method further includes sequentially forming, on the third area, a second semiconductor layer doped to have the first conductivity type and containing indium, a light emitting layer containing indium, and a third semiconductor layer doped to have the second conductivity type. An indium content of the light emitting layers formed in the first area, the second area, and the third area are different from each other. The second semiconductor layer formed on an area among the first area, the second area, and the third area where the light emitting layer having a highest indium content is also formed on has a multilayer structure. The multilayer structure includes first layers containing indium and second layers alternately stacked with the first layers.

In an embodiment, each of the second semiconductor layers on an area among the first area, the second area, and the third area other than the area on which the light emitting layer having the highest indium content is formed may be formed as a single layer structure.

A light emitting element array according to some embodiments may include multiple light emitting elements including a first light emitting element and a second light emitting element that emit light of different colors than one another. In some embodiments, the indium content of the light emitting layer of the first light emitting element may be higher than the indium content of the light emitting layer of the second light emitting element, and the semiconductor layer disposed under the light emitting layer of the first light emitting element may be formed having multiple layers containing indium. In some embodiments, the semiconductor layer disposed under the light emitting layer of the second light emitting element may be formed as a single layer containing indium.

According to various embodiments, light emitting elements that emit light of different colors than one another may be manufactured with relatively high quality on a (e.g., a single) substrate, and the quality of the first light emitting element may be improved by injecting indium into the light emitting layer of the first light emitting element containing indium at a relatively higher content. Accordingly, manufacturing efficiency of the light emitting element array and a display device including the light emitting element array may be increased, and manufacturing cost may be reduced. Further, the quality of the light emitting element array and the display device including the light emitting element array may be improved by differentiating or optimizing the structure and/or material of the light emitting elements according to the emission wavelength(s) and/or the indium content of the light emitting layer of the light emitting elements.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 is a plan view schematically showing a light emitting element array according to an embodiment.

FIG. 2 is a plan view schematically showing the light emitting element array according to an embodiment.

FIG. 3 is a perspective view schematically showing a part of the light emitting element array according to an embodiment.

FIG. 4 is a cross-sectional view schematically showing a part of the light emitting element array according to an embodiment.

FIG. 5 is a cross-sectional view schematically showing the light emitting element array according to an embodiment.

FIG. 6 is a cross-sectional view schematically showing the light emitting element array according to an embodiment.

FIG. 7 is a cross-sectional view schematically showing area A1 of FIG. 5 in more detail according to an embodiment.

FIG. 8 is a cross-sectional view schematically showing area A1 of FIG. 5 in more detail according to an embodiment.

FIG. 9 is a cross-sectional view schematically showing a second semiconductor layer of a first light emitting element according to an embodiment.

FIG. 10 is a cross-sectional view schematically showing area A1 of FIG. 5 in more detail according to an embodiment.

FIG. 11 is a cross-sectional view schematically showing area A2 of FIG. 5 in more detail according to an embodiment.

FIGS. 12 to 25 are cross-sectional views schematically showing a light emitting element array at various stages of manufacture according to an embodiment.

FIG. 26 is a perspective view schematically illustrating a display device according to an embodiment.

FIG. 27 is a plan view schematically showing an example of area A3 of FIG. 26 according to an embodiment.

FIG. 28 is a cross-sectional view schematically illustrating a display panel according to an embodiment.

FIG. 29 is a cross-sectional view schematically illustrating the display panel according to an embodiment.

FIG. 30 is a cross-sectional view schematically illustrating the display panel according to an embodiment.

FIG. 31 is a diagram schematically illustrating a virtual reality device including a display device according to an embodiment.

FIG. 32 is a diagram schematically illustrating a smart device including a display device according to an embodiment.

FIG. 33 schematically illustrates an automobile dashboard and center fascia including display devices according to an embodiment.

FIG. 34 is a diagram schematically illustrating a transparent display device including a display device according to an embodiment.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. In a case that an embodiment may be implemented differently, a specific process order may be performed differently from the described order. For example, two consecutively described processes may be performed substantially at the same time or performed in an order opposite the described order. Also, like reference numerals and/or reference characters denote like elements.

In a case that an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. However, in a case that an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items—it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the term “substantially,” if used herein, and unless otherwise specified, may mean within 5% of a referenced value. For example, substantially perpendicular may mean within ±5% of being parallel. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, various embodiments will be described with reference to the accompanying drawings.

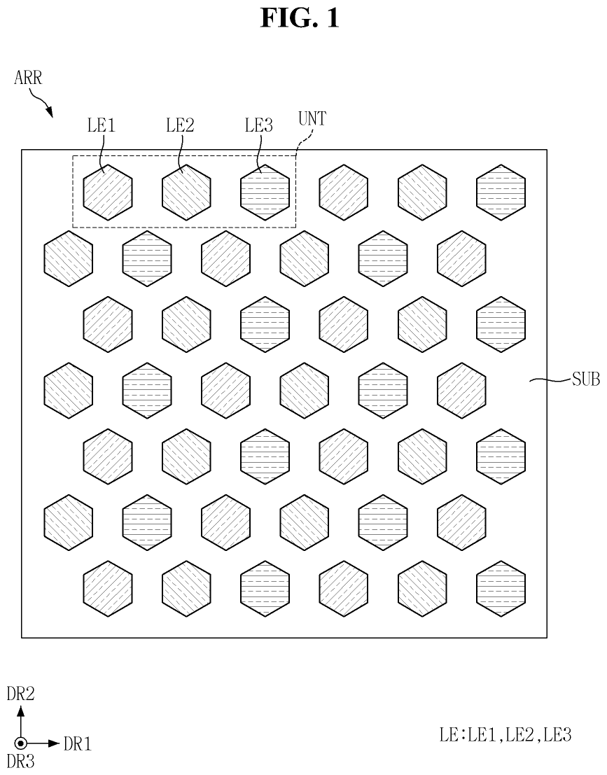

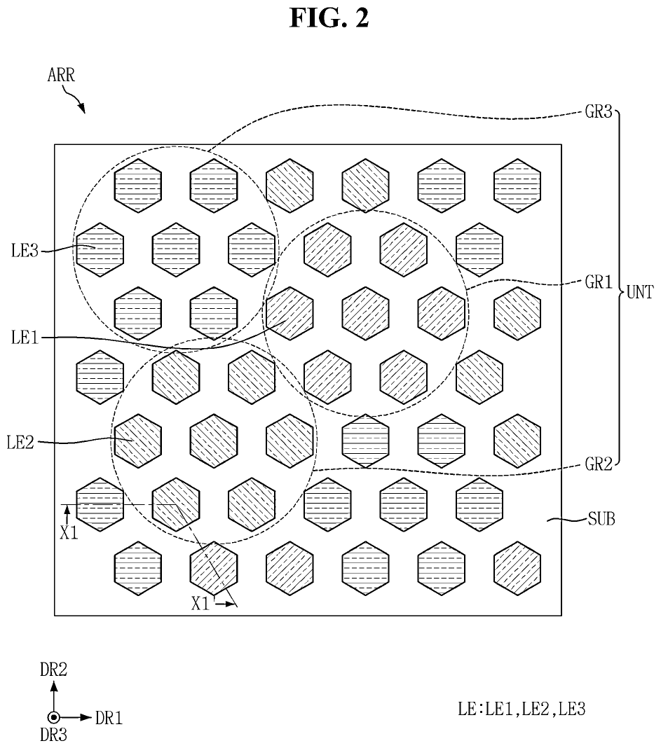

FIG. 1 is a plan view showing a light emitting element array ARR according to an embodiment. FIG. 2 is a plan view showing the light emitting element array ARR according to an embodiment. For example, FIGS. 1 and 2 show different embodiments with respect to the disposition of light emitting elements, such as light emitting element LE.

FIGS. 1 and 2 show a first direction DR1, a second direction DR2, and a third direction DR3 that are perpendicular to each other. For example, the first direction DR1 and the second direction DR2 are perpendicular to each other, and may define a plane parallel (or substantially parallel) to the bottom surface of the light emitting element LE or a substrate SUB. The third direction DR3 may be perpendicular to both the first direction DR1 and the second direction DR2. For example, the third direction DR3 may be a height direction or a thickness direction of the substrate SUB or the light emitting element LE.

Referring to FIGS. 1 and 2, the light emitting element array ARR may include the substrate SUB and the light emitting elements (e.g., light emitting element LE) disposed on the substrate SUB. Hereinafter, the light emitting elements may be collectively or individually referenced as light emitting element(s) LE. Although it is illustrated in FIGS. 1 and 2 that the substrate SUB has a rectangular planar shape in a view in the third direction DR3, the shape of the substrate SUB may be variously changed. Hereinafter, a planar shape of an element will refer to the shape of that element in a view in the third direction DR3. In some implementations, the substrate SUB may have another polygonal planar shape, a circular planar shape, an oval planar shape, an elliptical planar shape, a free-form planar shape, or another planar shape.

In an embodiment, the light emitting element array ARR may include the plurality of light emitting elements LE that emit light of different colors. For example, the light emitting elements LE may include a first light emitting element LE1 that emits light of a first color, a second light emitting element LE2 that emits light of a second color, and a third light emitting element LE3 that emits light of a third color. In an embodiment, the light of the first color, the light of the second color, and the light of the third color may be red light, green light, and blue light, respectively, but are not limited to these examples. In some embodiments, the light emitting element array ARR may include a plurality of first light emitting elements LE1, a plurality of second light emitting elements LE2, and a plurality of third light emitting elements LE3.

In an embodiment, the light emitting elements LE may, but not necessarily, have a hexagonal planar shape. For example, the light emitting elements LE may have another polygonal planar shape, a circular planar shape, an oval planar shape, an elliptical planar shape, a free-form planar shape, or another planar shape.

The light emitting elements LE may be arranged in various shapes or patterns. In an embodiment, as shown in FIG. 1, in a row extending in the first direction DR1, one first light emitting element LE1, one second light emitting element LE2, and one third light emitting element LE3 may be arranged consecutively or sequentially, and the first light emitting element LE1, the second light emitting element LE2, and the third light emitting element LE3 may constitute one (or a) light emitting element unit (or group) UNT capable of displaying light of various colors. The arrangement order of the first light emitting element LE1, the second light emitting element LE2, and the third light emitting element LE3 may vary depending on embodiments.

In some embodiments, such as shown in FIG. 2, at least two first light emitting elements LE1 may be arranged adjacent to each other along the first direction DR1 and/or the second direction DR2, and the at least two first light emitting elements LE1 may constitute one (or a) first light emitting element group GR1. For example, each first light emitting element group GR1 may include at least two first light emitting elements LE1 that are arranged adjacent to each other. Similarly, each second light emitting element group GR2 may include at least two second light emitting elements LE2 that are arranged adjacent to each other, and each third light emitting element group GR3 may include at least two third light emitting elements LE3 that are arranged adjacent to each other. As shown in FIG. 2, the first light emitting element group GR1 includes seven first light emitting elements LE1, the second light emitting element group GR2 includes seven second light emitting elements LE2, and the third light emitting element group GR3 includes seven light emitting elements LE3, but embodiments are not limited to this example. In some implementations, at least one of the first light emitting element group GR1, the second light emitting element group GR2, and the third light emitting element group GR3 may include less than seven, but more than two light emitting elements LE capable of displaying a same color, or greater than seven light emitting elements LE capable of displaying a same color. To this end, at least one of the first light emitting element group GR1, the second light emitting element group GR2, and the third light emitting element group GR3 may include a different number of light emitting elements LE than at least one other group among the first light emitting element group GR1, the second light emitting element group GR2, and the third light emitting element group GR3. In an embodiment, a first light emitting element group GR1, a second light emitting element group GR2, and a third light emitting element group GR3 adjacent to each other may constitute one (or a) light emitting element unit UNT.

In some implementations, the type and/or arrangement structure of the light emitting elements LE provided in the light emitting element array ARR, or the type, number, and/or arrangement structure of the light emitting elements LE constituting each light emitting element unit UNT may vary depending on embodiments.

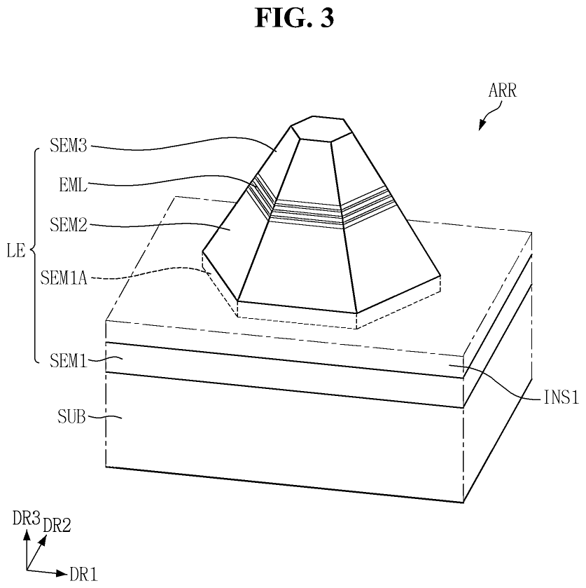

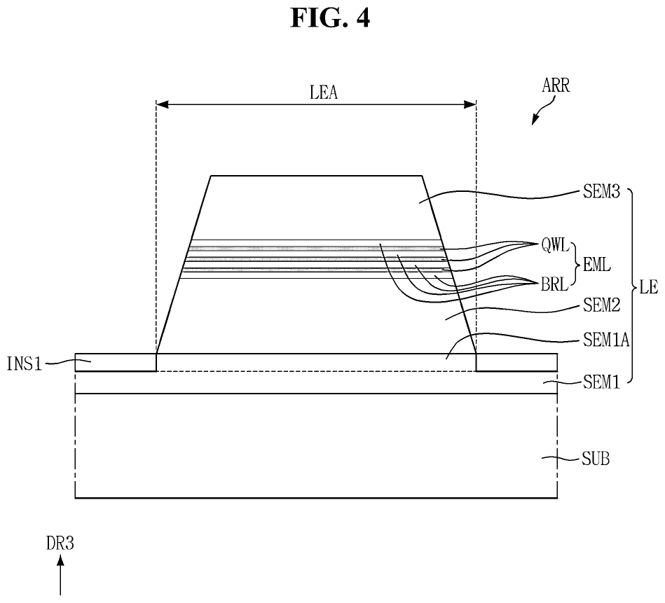

FIG. 3 is a perspective view schematically showing a part of the light emitting element array ARR according to an embodiment. FIG. 4 is a cross-sectional view schematically showing a part of the light emitting element array ARR according to an embodiment. For example, FIGS. 3 and 4 show one (or a) light emitting element LE provided in the light emitting element array ARR of FIGS. 1 and 2 and a periphery of the light emitting element LE. The light emitting element LE shown in FIGS. 3 and 4 may be one of the first light emitting element LE1, the second light emitting element LE2, and the third light emitting element LE3 of FIGS. 1 and 2.

Referring to FIGS. 1 to 4, the light emitting element array ARR may include the light emitting element LE disposed in each light emitting element area LEA. In an embodiment, the light emitting element array ARR may further include a first insulating layer INS1 disposed on the substrate SUB.

In an embodiment, the substrate SUB may be a manufacturing (or sacrificial) substrate for forming the light emitting elements LE. For example, the light emitting element array ARR may include a manufacturing substrate and the light emitting elements LE disposed and/or formed on the manufacturing substrate. However, embodiments are not limited to this example. For example, the light emitting elements LE may be manufactured on a manufacturing substrate and separated from the manufacturing substrate to be placed on a transfer substrate or a substrate (e.g., a backplane or another substrate of a display device) of an electronic device. For example, the substrate SUB may be a transfer substrate or a substrate of an electronic device. For example, the light emitting element array ARR may include a transfer substrate or a substrate of an electronic device, and the light emitting elements LE disposed on the transfer substrate or the substrate of the electronic device. Hereinafter, an embodiment in which the substrate SUB is a manufacturing substrate for manufacturing the light emitting elements LE will be described.

The substrate SUB may be a semiconductor substrate for forming the light emitting element LE. The substrate SUB may be a wafer or a manufacturing substrate suitable for epitaxial growth. For example, the light emitting elements LE may be formed on the substrate SUB by epitaxial growth.

In an embodiment, the substrate SUB may be a semiconductor substrate including at least one of silicon (Si), sapphire, GaAs, SiC, GaN, and ZnO, or another material. If epitaxial growth for manufacturing the light emitting elements LE may be readily performed, the type or material of the substrate SUB is not particularly limited.

A first semiconductor layer SEM1 of the light emitting element LE may be disposed on the substrate SUB. The light emitting element array ARR may further include a buffer layer (e.g., an undoped GaN layer) disposed between the substrate SUB and the first semiconductor layer SEM1.

In an embodiment, the light emitting elements LE are formed using a same substrate SUB, and parts of the light emitting elements LE may be integrally formed (or integral with one another) in the form of a common layer. For example, at least a part (e.g., a lower part of the first semiconductor layer SEM1) of the first semiconductor layer SEM1 of the light emitting elements LE may be formed entirely (or substantially entirely) on the substrate SUB in the form of a common layer. The light emitting elements LE may be electrically connected to each other through the first semiconductor layer SEM1. Another part (e.g., a seed layer SEM1A positioned at an upper part of the first semiconductor layer SEM1) of the first semiconductor layer SEM1 may be individually formed in each light emitting element area LEA, and may be surrounded (or circumscribed) by the first insulating layer INS1 (or a part of the first insulating layer INS1) in a view in the third direction DR3.

However, embodiments are not limited to the above-noted examples. For example, the light emitting elements LE manufactured on the substrate SUB may be separated from the substrate SUB and transferred or bonded to another substrate or electronic device so that a part (e.g., a lower part formed in the form of the common layer) of the first semiconductor layer SEM1 or the entire (or substantially entire) first semiconductor layer SEM1 including the seed layer SEM1A may be separated from the light emitting elements LE. In some implementations, the light emitting elements LE may not include the first semiconductor layer SEM1.

The first insulating layer INS1 may be disposed on a part of the first semiconductor layer SEM1 or the substrate SUB, and may have an opening corresponding to each light emitting element area LEA. For example, in a view in the third direction DR3 from a plane defined by the first direction DR1 and the second direction DR2, the first insulating layer INS1 (or a part of the first insulating layer INS1) may be disposed around the light emitting element LE to surround (or circumscribe) each light emitting element area LEA. In some implementations, at least a part of the first insulating layer INS1 may be disposed between the light emitting element areas LEA, and may include an opening corresponding to the planar shape of the light emitting element LE.

The first insulating layer INS1 may include at least one insulating material. For instance, the insulating material(s) may be at least one of silicon oxide (SiOₓ) (e.g., SiO₂), silicon nitride (SiNₓ) (e.g., Si₃N₄), aluminum oxide (AlₓO_{y}(e.g., Al₂O₃), titanium oxide (TiₓO_{y}) (e.g., TiO₂), and hafnium oxide (HfOₓ), or another insulating material. In an embodiment, the first insulating layer INS1 may include a material suitable for use as a mask in a process of forming the light emitting element LE, but is not limited to this example. For instance, a material of the first insulating layer INS1 suitable for use as a mask may be selected based on an etch selectivity, light sensitivity, bond strength, etc., of the material in association with various etching conditions or parameters.

The light emitting element LE may be disposed in each light emitting element area LEA defined (or at least partially bounded) by the opening of (or in) the first insulating layer INS1. The light emitting element LE may have various forms depending on embodiments. The light emitting element LE may include a side surface that is substantially perpendicular to or inclined (or oblique) with respect to a surface of the substrate SUB on which the light emitting element LE is disposed. For example, the light emitting element LE may have a hexagonal frustum shape in a view in, for instance, a direction perpendicular to the third direction DR3, but the shape of the light emitting element LE is not limited to this example.

In an embodiment, the light emitting element LE may be an inorganic light emitting element made of at least one inorganic material. For example, the light emitting element LE may be an inorganic light emitting diode made of (or including) a nitride-based semiconductor material (e.g., at least one of GaN, AlGaN, GaAlN, InGaN, InAlGaN, AlN, and InN, or another nitride-based semiconductor material), and/or another inorganic material. The light emitting element LE may emit light of a specific color or light in a range of wavelengths typically associated with a given color. For example, the light emitting element LE may emit red light (e.g., light with a wavelength in a range of approximately 620 nm to approximately 750 nm), green light (e.g., light with a wavelength in a range of approximately 500 nm to approximately 570 nm), blue light (e.g., light with a wavelength in a range of approximately 450 nm to approximately 500 nm), or light of another color.

In an embodiment, the light emitting element LE may be a micro light emitting diode (micro LED) having a relatively small size in the micrometer (μm) range. For example, the light emitting element LE may be a micro LED having lengths (or heights or other dimensions) in the first direction DR1, the second direction DR2, and the third direction DR3 that are in a range of hundreds of nanometers to hundreds of micrometers. Each of the lengths of the light emitting element LE in the first direction DR1, the second direction DR2, and the third direction DR3 may be approximately 100 μm or less, but embodiments are not limited to these example sizes.

The light emitting element LE may include the first semiconductor layer SEM1, a second semiconductor layer SEM2, a light emitting layer EML, and a third semiconductor layer SEM3 that are sequentially disposed on the substrate SUB. However, embodiments are not limited to these examples. For example, the light emitting element LE may include only a part (e.g., the seed layer SEM1A) of the first semiconductor layer SEM1, or may not include the first semiconductor layer SEM1.

In an embodiment, the light emitting element LE may further include a protective layer surrounding (or covering) the outer (or exposed) peripheral surfaces (e.g., side surfaces) of the second semiconductor layer SEM2, the light emitting layer EML, and/or the third semiconductor layer SEM3. The first insulating layer INS1 of a larger size may be provided to surround (or cover) the outer (or exposed) peripheral surfaces (e.g., side surfaces) of the second semiconductor layer SEM2, the light emitting layer EML, and/or the third semiconductor layer SEM3.

The first semiconductor layer SEM1 may be disposed on the substrate SUB. The first semiconductor layer SEM1 may be doped with a first conductivity type. For example, the first semiconductor layer SEM1 may include a semiconductor material including a first conductivity type dopant.

In an embodiment, the first semiconductor layer SEM1 may include a nitride-based semiconductor material and a first conductivity type dopant doped into the nitride-based semiconductor material. In an embodiment, the first semiconductor layer SEM1 may not contain indium (In). For example, the first semiconductor layer SEM1 may be an n-type semiconductor layer (e.g., n-GaN layer) made of a nitride-based semiconductor material that does not contain indium and doped with an n-type dopant, such as at least one of Si, Ge, Sn, and/or the like, but embodiments are not limited to this example.

In an embodiment, at least a part of the first semiconductor layer SEM1 surrounded (or circumscribed) by the first insulating layer INS1 in a view in, for example, the third direction DR3 (such as the seed layer SEM1A), may be a layer (e.g., an n-GaN seed layer) for relatively smooth (or uniform) growth of the second semiconductor layer SEM2.

In describing embodiments, a case in which the seed layer SEM1A formed in each light emitting element area LEA is a part of the first semiconductor layer SEM1 has been described, but embodiments are not limited to this example. For example, the lower part (e.g., n-GaN common layer) of the first semiconductor layer SEM1 disposed entirely on the substrate SUB and shared by a plurality of light emitting elements LE may be distinguished or considered as a separate element from the seed layer SEM1A. In some implementations, at least one of a lower part of the first semiconductor layer SEM1 and the seed layer SEM1A may be referred to as the first semiconductor layer SEM1.

The second semiconductor layer SEM2 may be disposed on the first semiconductor layer SEM1. For example, the second semiconductor layer SEM2 may be disposed between the first semiconductor layer SEM1 and the light emitting layer EML in the third direction DR3.

In an embodiment, the second semiconductor layer SEM2 may contain indium, and may be doped. For example, the second semiconductor layer SEM2 may include a nitride-based semiconductor material containing indium (e.g., InGaN, InAlGaN, and/or the like) and a first conductivity type dopant (e.g., an n-type dopant, such as at least one of Si, Ge, Sn, and/or the like) doped into the nitride-based semiconductor material. For example, the second semiconductor layer SEM2 may be formed of a single semiconductor layer (e.g., n-InGaN layer) containing indium and doped with a first conductivity type. In some embodiments, the second semiconductor layer SEM2 may be formed of multiple layers including first layers (e.g., n-InGaN layers) containing indium and doped with a first conductivity type and second layers alternately stacked with the first layers. Each of the second layers may be a doped or undoped layer (e.g., a GaN layer, an n-GaN layer, and/or the like) that does not substantially contain indium. In an embodiment, the indium content (or composition) of the second semiconductor layer SEM2 (or the first layer of the second semiconductor layer SEM2) may be lower than or equal to the indium content (or composition) of the light emitting layer EML (or quantum well layer QWL).

In an embodiment, the second semiconductor layer SEM2 of the light emitting element LE in which the indium content of the light emitting layer EML is highest among the first light emitting element LE1, the second light emitting element LE2, and the third light emitting element LE3 may be multiple layers in which the first layer and the second layer are alternately stacked on (or with) each other. For example, the light emitting layer EML of the first light emitting element LE1, which emits first color light (e.g., red light) of a relatively long wavelength (or range of wavelengths), may have a higher indium content compared to the light emitting layers EML of the second light emitting element LE2 and the third light emitting element LE3, and the second semiconductor layer SEM2 of the first light emitting element LE1 may be multiple layers in which the first layer and the second layer are alternately and/or repeatedly stacked on each other. The second semiconductor layer SEM2 of at least one of the second light emitting element LE2 and the third light emitting element LE3 may be formed of a single semiconductor layer containing indium and doped with a first conductivity type. For example, the second light emitting element LE2 may emit second color light (e.g., green light) of a wavelength (or range of wavelengths) shorter than that of the first color light emitted from the first light emitting element LE1, and the second semiconductor layer SEM2 of the second light emitting element LE2 may be formed of a single semiconductor layer containing indium and doped with a first conductivity type. Further, the third light emitting element LE3 may emit third color light (e.g., blue light) of a wavelength (or range of wavelengths) shorter than that of the second color light emitted from the second light emitting element LE2, and the second semiconductor layer SEM2 of the third light emitting element LE3 may be formed of a single semiconductor layer containing indium and doped with a first conductivity type.

The second semiconductor layer SEM2 may reduce lattice mismatch by lattice matching. For example, by disposing the second semiconductor layer SEM2 containing indium between the first semiconductor layer SEM1 and the light emitting layer EML, stress (e.g., in-plane stress) caused, at least in part, by lattice constant difference between the first semiconductor layer SEM1 and the light emitting layer EML may be reduced. Accordingly, in a step of forming the light emitting layer EML on the second semiconductor layer SEM2, indium may be readily injected into the light emitting layer EML according to a target indium composition, and a relatively high-quality light emitting layer EML with reduced defects may be formed. For example, also in a case of manufacturing a relatively long-wavelength light emitting element LE (e.g., the first light emitting element LE1, such as a red light emitting element) in which the indium content of the light emitting layer EML (or the quantum well layer QWL) is approximately 30% or more, the second semiconductor layer SEM2 may be firstly formed on the first semiconductor layer SEM1 and the light emitting layer EML may be formed on the second semiconductor layer SEM2 so that indium may be readily injected into the quantum well layer QWL, and the quality of the light emitting element LE may be improved.

Further, since the second semiconductor layer SEM2 may be doped (e.g., doped with a first conductivity type), light emission of the second semiconductor layer SEM2 may be prevented or reduced. In an embodiment, the doping concentration of the second semiconductor layer SEM2 (or the first layer of the second semiconductor layer SEM2) may be approximately 10¹⁶ atoms of dopant/cm³ or higher. Accordingly, unintentional light emission of the second semiconductor layer SEM2 may be effectively prevented. For example, even if the second semiconductor layer SEM2 contains indium, non-emission recombination of carriers (e.g., electrons or holes) may be caused, at least in part, by the dopant doped into the second semiconductor layer SEM2 to prevent the second semiconductor layer SEM2 from generating light of a wavelength different from a wavelength of light emitted from the light emitting layer EML. Accordingly, the color purity of the light emitting element LE may be improved.

The second semiconductor layer SEM2 may be formed to have a thickness in consideration of at least one of the lattice matching effect, the manufacturing efficiency of the light emitting element LE, and the luminous efficiency of the light emitting element LE. For example, the second semiconductor layer SEM2 (or the first layer of the second semiconductor layer SEM2) may be formed to have a thickness of approximately 10 nm or more in order to obtain a desired lattice matching effect. In an embodiment, the thickness of each of the first layers forming the second semiconductor layer SEM2 may be approximately 10 nm or more, and the total thickness of the second semiconductor layer SEM2 may be approximately 300 nm or more. Accordingly, a relatively high-quality light emitting layer EML may be formed on the second semiconductor layer SEM2.

The light emitting layer EML may be disposed on the second semiconductor layer SEM2. For example, the light emitting layer EML may be disposed between the second semiconductor layer SEM2 and the third semiconductor layer SEM3 in the third direction DR3. The light emitting layer EML may emit light by recombination of electron-hole pairs generated according to an electrical signal applied through the first semiconductor layer SEM1 (or the second semiconductor layer SEM2) and the third semiconductor layer SEM3.

The light emitting layer EML may include a nitride-based semiconductor material or another semiconductor material, and may have a single or multiple quantum well structure. For example, the light emitting layer EML may include at least one quantum well layer QWL including a nitride-based semiconductor material containing indium. In an embodiment, the quantum well layer QWL may include a nitride-based semiconductor material containing indium at a content higher than or equal to that of the second semiconductor layer SEM2 (or the first layer of the second semiconductor layer SEM2). In an embodiment, the light emitting layer EML may have a multiple quantum well structure in which a plurality of quantum well layers QWL containing InGaN, and a plurality of barrier layers BRL containing GaN, AlGaN, or GaAlN are disposed alternately and/or repeatedly.

In an embodiment, the light emitting layer EML may emit light in a visible light wavelength band, for example, light in a wavelength band of approximately 400 nm to approximately 900 nm. For example, the light emitting layer EML may emit blue light having a peak wavelength in a range of approximately 440 nm to approximately 480 nm, green light having a peak wavelength in a range of approximately 510 nm to approximately 550 nm, or red light having a peak wavelength in a range of approximately 610 nm to approximately 750 nm (e.g., in a range of approximately 610 nm to approximately 650 nm). The light emitting layer EML may emit light whose color or wavelength band is different from the color or the wavelength band exemplified above.

In an embodiment, the color of light emitted from the light emitting layer EML may be adjusted or changed by adjusting the content of indium contained in the light emitting layer EML. For example, the light emitting layer EML (or the quantum well layer QWL of the light emitting layer EML) of the first light emitting element LE1 may contain indium at a content of approximately 30% to approximately 40% so that the first light emitting element LE1 may emit red light. The light emitting layer EML (or the quantum well layer QWL of the light emitting layer EML) of the second light emitting element LE2 may contain indium at a content of approximately 20% to less than approximately 30% so that the second light emitting element LE2 may emit green light. The light emitting layer EML (or the quantum well layer QWL of the light emitting layer EML) of the third light emitting element LE3 may contain indium at a content of approximately 10% to less than approximately 20% so that the third light emitting element LE3 may emit blue light.

The third semiconductor layer SEM3 may be disposed on the light emitting layer EML. The third semiconductor layer SEM3 may be doped with a second conductivity type. For example, the third semiconductor layer SEM3 may include a semiconductor material including a second conductivity type dopant.

In an embodiment, the third semiconductor layer SEM3 may include a nitride-based semiconductor material and a second conductivity type dopant doped into the nitride-based semiconductor material. For example, the third semiconductor layer SEM3 may be a p-type semiconductor layer (e.g., a p-GaN layer, a p-InGaN layer, and/or the like) doped with a p-type dopant, such as at least one of Mg, Zn, Ca, Se, Ba, and/or the like, but is not limited to these examples.

In an embodiment, the third semiconductor layer SEM3 may be made of a nitride-based semiconductor material containing indium, similarly to the second semiconductor layer SEM2, and may include a second conductivity type dopant. For example, the third semiconductor layer SEM3 may be a p-type semiconductor layer (e.g., a p-InGaN layer) made of a nitride-based semiconductor material containing indium (e.g., InGaN) and doped with a p-type dopant. In an embodiment, the third semiconductor layer SEM3 may have a single layer structure, but in some implementations, may have a multiple layer structure.

In an embodiment, a width (e.g., the length in the first direction DR1 or the second direction DR2) of each light emitting element area LEA or the light emitting element LE disposed in the light emitting element area LEA may be on the order of hundreds of nanometers (e.g., approximately 400 nm to approximately 800 nm). Since the second semiconductor layer SEM2 and the third semiconductor layer SEM3 are made of a nitride-based semiconductor material containing indium (e.g., InGaN), a relatively fine-sized light emitting element LE having a width on the order of hundreds of nanometers may be manufactured with relatively high quality.

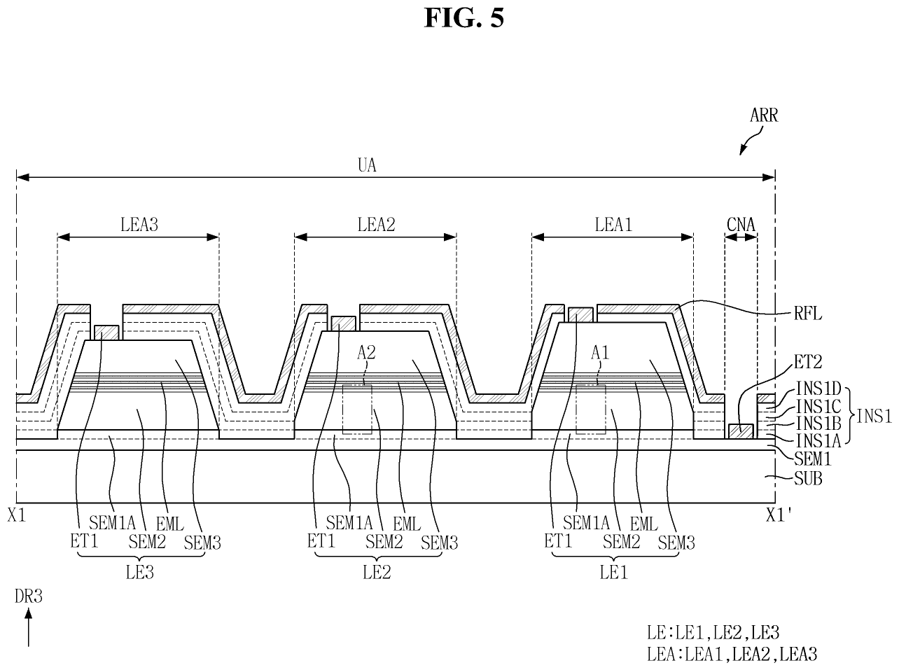

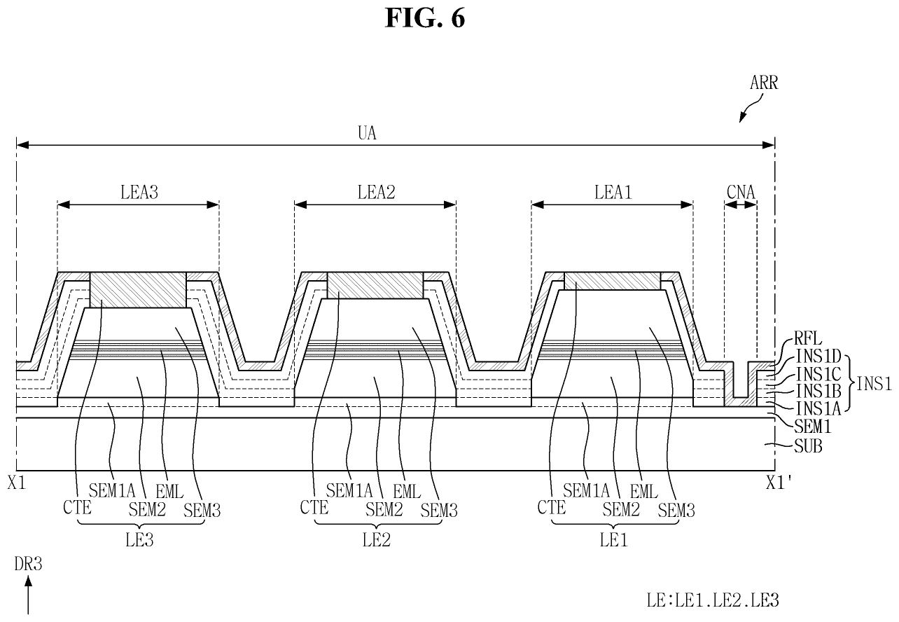

FIG. 5 is a cross-sectional view schematically showing the light emitting element array ARR according to an embodiment. FIG. 6 is a cross-sectional view schematically showing the light emitting element array ARR according to an embodiment. For example, FIGS. 5 and 6 show embodiments of the cross section of the light emitting element array ARR taken along sectional line X1-X1′, and show different embodiments in relation to electrodes that may be formed in the light emitting element array ARR.

Referring to FIGS. 5 and 6 in addition to FIGS. 1 to 4, the light emitting element array ARR may include the first light emitting element LE1, the second light emitting element LE2, and the third light emitting element LE3 respectively disposed in a first light emitting element area LEA1, a second light emitting element area LEA2, and a third light emitting element area LEA3. Each of the first light emitting element LE1, the second light emitting element LE2, and the third light emitting element LE3 may include the first semiconductor layer SEM1 (and/or the seed layer SEM1A), the second semiconductor layer SEM2, the light emitting layer EML, and the third semiconductor layer SEM3 that are sequentially disposed on the substrate SUB.

The light emitting element array ARR may further include the first insulating layer INS1 covering (or overlapping in the third direction DR3) at least a part of each of the light emitting elements LE. For example, the first insulating layer INS1 may cover at least a part of each of the light emitting elements LE including the side (or exposed peripheral) surfaces of the light emitting elements LE. In an embodiment, the light emitting element array ARR may further include a reflective layer RFL disposed on the first insulating layer INS1.

In an embodiment, the first insulating layer INS1 may include one or more portions that function as a mask for sequentially forming the first light emitting element LE1, the second light emitting element LE2, and the third light emitting element LE3. For example, the first insulating layer INS1 may include a first portion INS1A (also referred to as “first mask layer”) that defines (or at least partially bounds) the third light emitting element area LEA3 for forming the third light emitting element LE3, a second portion INS1B (also referred to as “second mask layer”) that defines (or at least partially bounds) the second light emitting element area LEA2 for forming the second light emitting element LE2, and a third portion INS1C (also referred to as “third mask layer”) that defines (or at least partially bounds) the first light emitting element area LEA1 for forming the first light emitting element LE1 in one or more steps (or processes) of manufacturing the light emitting element array ARR.

In an embodiment, the first insulating layer INS1 may have different thicknesses depending on areas or portions. For example, the first insulating layer INS1 may have different thicknesses in the first light emitting element area LEA1, the second light emitting element area LEA2, and the third light emitting element area LEA3 (e.g., portions respectively covering (or overlapping in, for instance, the third direction DR3) the first light emitting element LE1, the second light emitting element LE2 and the third light emitting element LE3).

The first portion INS1A of the first insulating layer INS1 may be disposed between and/or around the light emitting element areas LEA in a view in, for instance, the third direction DR3. For example, the first portion INS1A of the first insulating layer INS1 may be disposed on a part (e.g., a lower part formed entirely (or substantially entirely) on the substrate SUB) of the first semiconductor layer SEM1 between and/or around the light emitting element areas LEA in a view in the third direction DR3.

The second portion INS1B of the first insulating layer INS1 may cover (or overlap) at least a part (e.g., a part of an upper surface and a side surface) of the third light emitting element LE3 in a view in, for instance, the third direction DR3. The second portion INS1B of the first insulating layer INS1 may be disposed between and/or around the light emitting element areas LEA in a view in, for instance, the third direction DR3. For example, the second portion INS1B of the first insulating layer INS1 may be disposed on the first portion INS1A of the first insulating layer INS1 between and/or around the light emitting element areas LEA in a view in the third direction DR3.

The third portion INS1C of the first insulating layer INS1 may cover (or overlap) at least a part of each of the second light emitting element LE2 and the third light emitting element LE3 in, for instance, the third direction DR3. The third portion INS1C of the first insulating layer INS1 may be disposed between and/or around the light emitting element areas LEA in a view in, for instance, the third direction DR3. For example, the third portion INS1C of the first insulating layer INS1 may be disposed on the second portion INS1B of the first insulating layer INS1 between and/or around the light emitting element areas LEA in a view in the third direction DR3.

In an embodiment, the first insulating layer INS1 may further include a fourth portion INS1D (also referred to as “passivation layer”) that covers (or overlaps in the third direction DR3) at least a part of each of the first light emitting element LE1, the second light emitting element LE2, and the third light emitting element LE3, and protects the light emitting elements LE. The fourth portion INS1D of the first insulating layer INS1 may be disposed between and/or around the light emitting element areas LEA in a view in, for instance, the third direction DR3. For example, the fourth portion INS1D of the first insulating layer INS1 may be disposed on the third portion INS1C of the first insulating layer INS1 between and/or around the light emitting element areas LEA in a view in the third direction.

In an embodiment, the light emitting element array ARR may include at least one electrode formed in (or as part of) the light emitting elements LE, and the first insulating layer INS1 may be opened in the area where the electrode is disposed. For example, the first insulating layer INS1 may include openings that overlap a first electrode ET1 of each of the light emitting elements LE and a second electrode ET2 electrically connected to the light emitting elements LE. In some implementations, an outer boundary of the openings in the first insulating layer INS1 may respectively circumscribe a corresponding one of the first electrode ET1 and the second electrode ET2 in a view in the third direction DR3.

The reflective layer RFL may cover (or overlap in, for instance, the third direction DR3) at least a part of the light emitting elements LE. For example, the reflective layer RFL may be disposed on the first insulating layer INS1 to cover the side (or exposed peripheral) surface of each of the light emitting elements LE. The reflective layer RFL may further cover (or overlap in, for instance, the third direction DR3) at least a part of upper surfaces of the light emitting elements LE.

In an embodiment, the light emitting element array ARR may include at least one electrode formed in the light emitting elements LE, and the reflective layer RFL may be opened in the area where the electrode is disposed. For example, the reflective layer RFL may include openings that overlap the first electrode ET1 of each of the light emitting elements LE and the second electrode ET2 electrically connected to the light emitting elements LE in a view in, for instance, the third direction DR3. In some implementations, an outer boundary of the openings in the first insulating layer INS1 may respectively circumscribe a corresponding one of the first electrode ET1 and the second electrode ET2 in a view in the third direction DR3.

In an embodiment, the reflective layer RFL may include metal having a relatively high light reflectivity. For example, the reflective layer RFL may include at least one metal having relatively high reflectivity, such as at least one of aluminum (Al), molybdenum (Mo), titanium (Ti), copper (Cu), silver (Ag), magnesium (Mg), platinum (Pt), palladium (Pd), gold (Au), nickel (Ni), neodymium (Nd), iridium (Ir), and chromium (Cr), or another reflective material. In some embodiments, the reflective layer RFL may be formed as a distributed Bragg reflector, or the like.

The reflective layer RFL may reflect light generated (or emitted) from each light emitting element LE. For example, the reflective layer RFL may reflect light generated from the light emitting layer EML of each light emitting element LE and directed (or propagating) toward a side (or peripheral) surface of the light emitting element LE to recirculate light. Accordingly, the loss of light generated from the light emitting element LE may be prevented or reduced, and the light emission efficiency of the light emitting element LE may be further improved. In some implementations, an optical thickness of the reflective layer RFL may cause, at least in part, constructive interference, and in this manner, further increase respective light emitting efficiencies of the light emitting elements LE. To this end, the optical thickness of the reflective layer RFL may be different in one or more of the first light emitting area LEA1, the second light emitting area LEA2, and the third light emitting area LEA3. This may also increase the respective light emitting efficiencies of the various light emitting elements LE.

In an embodiment, the light emitting element array ARR may further include at least one electrode electrically connected to the first semiconductor layer SEM1 or the third semiconductor layer SEM3 of each of the light emitting elements LE (or each of the light emitting elements LE of a light emitting element group, or each of the light emitting elements LE of a light emitting element unit UNT, or each of the light emitting elements LE in a unit area UA).

In an embodiment, the light emitting element array ARR may include respective first electrodes ET1 disposed on the third semiconductor layer SEM3 of each of the light emitting elements LE and the second electrode ET2 may be disposed on the first semiconductor layer SEM1 of the light emitting elements LE, such as shown in FIG. 5.

The first electrode ET1 may be a connection electrode for electrically connecting the third semiconductor layer SEM3 (or a contact electrode disposed on the third semiconductor layer SEM3) to another circuit element, electrode, wiring, and/or the like. In an embodiment, the first electrode ET1 may have a smaller size (e.g., a smaller planar area) than a corresponding size of the third semiconductor layer SEM3, and may be disposed on a part of the third semiconductor layer SEM3, but embodiments are not limited to this example.

In an embodiment, each first electrode ET1 may be disposed on (e.g., directly on) the third semiconductor layer SEM3 of a corresponding light emitting element LE and electrically connected to the third semiconductor layer SEM3. Each first electrode ET1 may be a component included in a corresponding light emitting element LE among the light emitting elements LE. In an embodiment, the first electrode ET1 may be electrically connected to an electronic device using the light emitting element array ARR, for example, a pixel electrode (or a bonding pad) provided in a corresponding pixel of a display device.

The second electrode ET2 may be a connection electrode for electrically connecting the first semiconductor layer SEM1 to another circuit element, electrode, wiring, and/or the like. In an embodiment, the second electrode ET2 may be, but is not necessarily limited to being, disposed in a contact area CNA located around (or partially around) or adjacent to the light emitting element areas LEA. In some embodiments, the contact area CNA may circumscribe (or partially circumscribe) one or more of the light emitting element areas LEA in a view in the third direction DR3. In an embodiment, the second electrode ET2 may be connected to a second pixel power line or a common electrode provided in a display device, as will become more apparent below.

In an embodiment, the second electrode ET2 may be an electrode shared by a plurality of light emitting elements LE. For example, the second electrode ET2 may be disposed on (e.g., directly on) the first semiconductor layer SEM1 shared by the first light emitting element LE1, the second light emitting element LE2, and the third light emitting element LE3 that are formed in at least one unit area UA and electrically connected to the first semiconductor layer SEM1. However, embodiments are not limited to this example. For example, the light emitting element array ARR may include a plurality of second electrodes ET2 whose number and/or resolution (or density) correspond to the number and/or resolution (or density) of the light emitting elements LE. For instance, the second electrodes ET2 may correspond 1:1 with the light emitting elements LE.

The first electrode ET1 and the second electrode ET2 may include at least one of metal, metal oxide, and other conductive materials. For example, the first electrode ET1 and the second electrode ET2 may include at least one of molybdenum (Mo), aluminum (Al), chromium (Cr), gold (Au), titanium (Ti), nickel (Ni), neodymium (Nd), and copper (Cu), but embodiments are not limited to these materials. In some implementations, respective materials of the first electrode ET1 and the second electrode ET2 may be equivalent to or different from one another.

In an embodiment, the light emitting element array ARR may include a transparent electrode CTE disposed on the third semiconductor layer SEM3 of each of the light emitting elements LE, such as shown in FIG. 6. The transparent electrode CTE, which may be a contact electrode that protects the third semiconductor layer SEM3 and electrically connects the third semiconductor layer SEM3 to at least one electrode, circuit element, wiring, and/or the like, may be provided in (or as part of) each light emitting element LE. For instance, each light emitting element LE may include a respective transparent electrode CTE, such as shown in FIG. 6.

The transparent electrode CTE may include at least one of metal, metal oxide, and other conductive materials. For example, the metal may be at least one of chromium (Cr), titanium (Ti), aluminum (Al), gold (Au), nickel (Ni), and copper (Cu), and/or an alloy including at least one of the metals. The oxide may be an oxide of at least one of the metals. In some implementations the transparent electrode CTE may include a transparent conductive material, such as at least one of indium tin oxide (ITO), indium zinc oxide (IZO), indium tin zinc oxide (ITZO), zinc oxide (ZnO), and indium oxide (In₂O₃), and/or another transparent conductive material. The transparent conductive material may be used alone or mixed (or combined) to form the transparent electrode CTE. Embodiments, however, are not limited to these examples.

In an embodiment, the transparent electrode CTE may be in contact (or direct contact) with (e.g., physical and/or electrical contact with) the reflective layer RFL, and may be electrically connected to at least one electrode, circuit element, wiring, and/or the like, through the reflective layer RFL. For example, the reflective layer RFL may be formed to be in contact with (e.g., direct physical and/or electrical contact with) the side (or peripheral) surface of the transparent electrode CTE, and may extend to the contact area CNA and used as a connection electrode (e.g., a bonding electrode) for electrically connecting the third semiconductor layer SEM3 to another circuit element, electrode, wiring, and/or the like. In an embodiment, the reflective layer RFL may be in contact with (e.g., direct physical and/or electrical contact with) the first semiconductor layer SEM1 inside the opening of the first semiconductor layer SEM1 formed in the contact area CNA. In some implementations, after manufacturing the light emitting elements LE, the first semiconductor layers SEM1 of the light emitting elements LE may be separated from each other. In some implementations, the first semiconductor layers SEM1 of the light emitting elements LE may be separated as part of manufacturing the light emitting elements LE. Further, the first semiconductor layers (e.g., the seed layer SEM1A of the first semiconductor layer SEM1 disposed in each light emitting element area LEA) of the separated light emitting elements LE may also be separated from the reflective layer RFL.

In some embodiments, the transparent electrodes CTE may be connected (e.g., directly connected) to bonding pads or electrodes of an electronic device using the light emitting elements LE without the connection being formed through (or using) the reflective layer RFL. In some implementations, the transparent electrodes CTE may be physically and/or electrically connected (e.g., directly connected) to bonding pads or electrodes of an electronic device using the light emitting elements LE without the connection being formed through (or using) the reflective layer RFL.

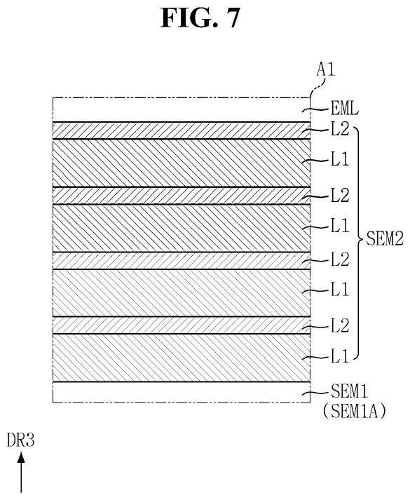

FIG. 7 is a cross-sectional view schematically showing area A1 of FIG. 5 in more detail according to an embodiment. For example, FIG. 7 shows an embodiment of the second semiconductor layer SEM2 of the first light emitting element LE1.

Referring to FIGS. 1 to 7, the second semiconductor layer SEM2 of the first light emitting element LE1 may have a multilayer structure including at least one pair of the first layer L1 and the second layer L2. For example, the second semiconductor layer SEM2 of the first light emitting element LE1 may have a multilayer structure in which at least two pairs of the first layers L1 and at least two pairs of the second layers L2 are included and the first layers L1 and the second layers L2 are disposed alternately and repeatedly with each other.

The first layer L1 may be a semiconductor layer containing indium. For example, the first layer L1 may be a semiconductor layer (e.g., an n-InGaN layer) containing indium and doped with a first conductivity type. In an embodiment, the first layer L1 may be a layer for readily injecting indium into the light emitting layer EML, and the indium content (or indium composition) of the first layer L1 may be lower than or equal to the indium content (or indium composition) of the light emitting layer EML or the quantum well layer QWL. At least because the first layer L1 is doped (e.g., doped with a first conductivity type), it is possible to prevent or reduce light from being generated in (or emitted from) the first layer L1. In an embodiment, the doping concentration of the first layer L1 may be 10¹⁶ atoms of dopant/cm³ or higher. Accordingly, it is possible to effectively prevent light from being generated in (or emitted from) the first layer L1.

In an embodiment, the indium content of the first layers L1 may be generally uniform or may change (or vary), such as gradually change. For example, the indium content of the first layers L1 may be substantially equivalent or similar to one another. In some embodiments, the indium content of the first layers L1 may change (e.g., increase), such as gradually increase, from one first layer L1 to another first layer L1 in a direction toward the light emitting layer EML. In some implementations, the indium content of any given first layer L1 may be uniform or vary, such as gradually vary (e.g., increase) with decreasing distance to the light emitting layer EML. Accordingly, indium may be readily injected into the first layers L1, and the quality of the first light emitting element LE1 may be improved.

The second layer L2 may be a semiconductor layer that does not contain indium. For example, the second layer L2 may be a doped or undoped semiconductor layer (e.g., an n-GaN layer) that does not contain indium.

At least because the second semiconductor layer SEM2 of the first light emitting element LE1 may be formed of multiple layers in which the first layers L1 and the second layers L2 are alternately disposed on each other, the quality of the first light emitting element LE1 may be improved. For example, in a case that the second semiconductor layer SEM2 (or the first layers L1) of the first light emitting element LE1 contains a higher content of indium compared to the second semiconductor layer SEM2 of the second light emitting element LE2 and/or the third light emitting element LE3, it is possible to prevent in-phase separation that might otherwise occur in a nitride-based semiconductor layer containing indium. It is also possible to manufacture a relatively high-quality first light emitting element LE1.

The thickness of the second semiconductor layer SEM2 and the thickness of each of the first layers L1 and the second layers L2 forming the second semiconductor layer SEM2 may be adjusted or changed in consideration of at least one of the lattice matching effect obtained by the second semiconductor layer SEM2, the manufacturing efficiency of the light emitting element LE, and the luminous efficiency of the light emitting element LE. For example, the thickness of each of the first layers L1 may be greater than the thickness of each of the second layers L2. Accordingly, the mobility of carriers may be secured while obtaining an appropriate (or determined) lattice matching effect.

In an embodiment, the thickness of each of the first layers L1 may be approximately 10 nm or more so that the lattice matching effect may be improved or secured. For example, the thickness of each of the first layers L1 may be in a range of approximately 10 nm to approximately 20 nm so that the first layers L1 may be formed more smoothly and/or appropriately and to secure a determined the lattice matching effect. In an embodiment, the thickness of each of the second layers L2 may be approximately 5 nm or less (e.g., in a range of approximately 1 nm to approximately 5 nm) so that carriers (e.g., electrons) may move more readily. In an embodiment, a total thickness of the second semiconductor layer SEM2 may be approximately 300 nm or more so that a determined lattice matching effect may be improved or secured.

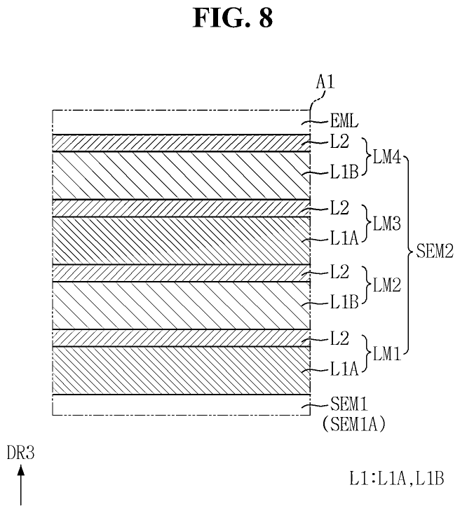

FIG. 8 is a cross-sectional view schematically showing area A1 of FIG. 5 in more detail according to an embodiment. For example, FIG. 8 shows an embodiment different from the embodiment shown in FIG. 7 in relation to the second semiconductor layer SEM2 of the first light emitting element LE1.

Referring to FIGS. 1 to 8, the second semiconductor layer SEM2 of the first light emitting element LE1 may include multiple laminates (or layers), which are sequentially disposed along the third direction DR3. Each of the laminates may include at least one of the first layer L1 and at least one of the second layer L2. Stated differently, each of the laminates may include at least one pair of layers, each pair of layers including a first layer L1 and a second layer L2. For example, the second semiconductor layer SEM2 of the first light emitting element LE1 may include first to fourth laminates LM1 to LM4, which are sequentially disposed on the first semiconductor layer SEM1 (e.g., the seed layer SEM1A) along the third direction DR3, each including at least one of the first layer L1 and at least one of the second layer L2. Further, the second semiconductor layer SEM2 of the first light emitting element LE1 may include the first layers L1 having different indium contents. For example, at least one laminate among the first to fourth laminates LM1 to LM4 may have a first layer L1 with an indium content different from an indium content of the first layers L1 of the other laminates among the first to fourth laminates LM1 to LM4. For example, two laminates disposed sequentially or consecutively with one another along the third direction DR3 may include the first layers L1 having different indium contents from one another.

In an embodiment, first layers L1B included in the second laminate LM2 and the fourth laminate LM4 may contain indium at a content that is at least approximately 5% lower than the indium content of those first layers L1A included in the first laminate LM1 and the third laminate LM3. For example, the first laminate LM1 may include the first layer L1A (also referred to as “first indium-containing layer”) containing indium at a first content and the second layer L2 on the first layer L1A, and the second laminate LM2 may include the first layer L1B (also referred to as “second indium-containing layer”) containing indium at a second content that is at least approximately 5% lower than the first content, and the second layer L2 on the first layer L1B. Further, the third laminate LM3 may include the first layer L1A (also referred to as “first indium-containing layer”) containing indium at the first content and the second layer L2 on the first layer L1A, and the fourth laminate LM4 may include the first layer L1B (also referred to as “second indium-containing layer”) containing indium at the second content that is at least approximately 5% lower than the first content, and the second layer L2 on the first layer L1B.

In an embodiment, the indium content of the first layers L1A included in the first laminate LM1 and the third laminate LM3 may be equivalent (or substantially equivalent) to (or with) each other, but embodiments are not limited to this example. For example, the indium content of the first layers L1A included in the first laminate LM1 and the third laminate LM3 may be different from each other. Further, in a case that each of the first laminate LM1 and the third laminate LM3 includes a plurality of first layers L1A, the indium content of the plurality of first layers L1A may be equivalent (or substantially equivalent) or different from each other.

The indium content of the first layers L1B included in the second laminate LM2 and the fourth laminate LM4 may be equivalent (or substantially equivalent) to (or with) each other, but embodiments are not limited to this example. For example, the indium content of the first layers L1B included in the second laminate LM2 and the fourth laminate LM4 may be different from each other. Further, in a case that each of the second laminate LM2 and the fourth laminate LM4 includes a plurality of first layers L1B, the indium content of the plurality of first layers L1B may be equivalent (or substantially equivalent) or different from each other.

In an embodiment, the indium content of the light emitting layer EML (or the quantum well layer QWL) of the first light emitting element LE1 that emits red light may be in a range of approximately 30% to approximately 40%, and the indium content of the first layer L1 containing indium at a higher content (e.g., the first content) among the first layers L1 forming the second semiconductor layer SEM2 of the first light emitting element LE1 may be lower than or equal to 40%. In an embodiment, the indium contents of the first layers L1 forming the second semiconductor layer SEM2 of the first light emitting element LE1 may be adjusted to be lower than or equal to the indium content of the quantum well layer QWL of the first light emitting element LE1, for example, to be lower than or equal to 30%. For example, the indium content of the first layer L1A containing indium at the first content among the first layers L1 forming the second semiconductor layer SEM2 of the first light emitting element LE1 may be in a range of approximately 25% to approximately 30%, and the indium content of the first layer L1B containing indium at the second content may be lower than or equal to approximately 25%. Accordingly, the lattice matching effect may be improved or optimized while readily forming the second semiconductor layer SEM2.

In an embodiment, to control or change the indium content of the first layers L1, the flow of an indium source may be adjusted or the growth temperature (or range of growth temperatures) of the first layers L1 may be adjusted. For example, to lower the indium content, the flow of the indium source may be changed (e.g., increased) or the growth temperature (or range of growth temperatures) of the first layers L1 may be increased.

In an embodiment, the laminates having different indium content from one another may be formed by processes of different temperatures (or different ranges of temperatures). For example, the semiconductor layers (e.g., the respective first layers L1A and the respective second layers L2) of the first laminate LM1 and the third laminate LM3 may be formed by regrowth (or growth) at a relatively low (or first) temperature (or first range of temperatures), and the semiconductor layers (e.g., the respective first layers L1B and the respective second layers L2) of the second laminate LM2 and the fourth laminate LM4 may be formed by regrowth (or growth) at a relatively high (or second) temperature (or second range of temperatures). The semiconductor layers (e.g., semiconductor layers of the second laminate LM2 and the fourth laminate LM4) re-grown (or grown) at a relatively high temperature may exhibit characteristics in which the surface roughness is reduced. At least because a part of the laminates forming the second semiconductor layer SEM2 may be formed by a relatively high-temperature process, the optical characteristics (e.g., light emission efficiency) of the light emitting element LE including the second semiconductor layers SEM2 may be improved.

In an embodiment, the light emission characteristics of the light emitting element LE may be improved or adjusted by adjusting or changing the position and/or thickness of at least one of the second laminate LM2 and the fourth laminate LM4. For example, by disposing the semiconductor layers of the second laminate LM2 and the fourth laminate LM4 at an intermediate layer and an uppermost layer of the second semiconductor layer SEM2, the light emission efficiency of the light emitting element LE may be increased.

Although FIG. 8 shows an embodiment in which the first laminate LM1 and the third laminate LM3 include the first layers L1A having equivalent (or substantially equivalent) indium content, and in which the second laminate LM2 and the fourth laminate LM4 include the first layers L1B having equivalent (or substantially equivalent) indium content, embodiments are not limited to this example. For example, the indium content of the first layer L1A of the first laminate LM1 and the indium content of the first layer L1A of the third laminate LM3 may be different from each other, and the indium content of the first layer L1A of the first laminate LM1 and the indium content of the first layer L1A of the third laminate LM3 may be higher than the indium content of the first layer L1B of the second laminate LM2 and the first layer L1B of the fourth laminate LM4, respectively. The indium content of the first layer L1B of the second laminate LM2 and the indium content of the first layer L1B of the fourth laminate LM4 may be different, the indium content of the first layer L1B of the second laminate LM2 and the indium content of the first layer L1B of the fourth laminate LM4 and may be lower than the indium content of the first layer L1A of the first laminate LM1 and the indium content of the first layer L1A and the third laminate LM3, respectively.

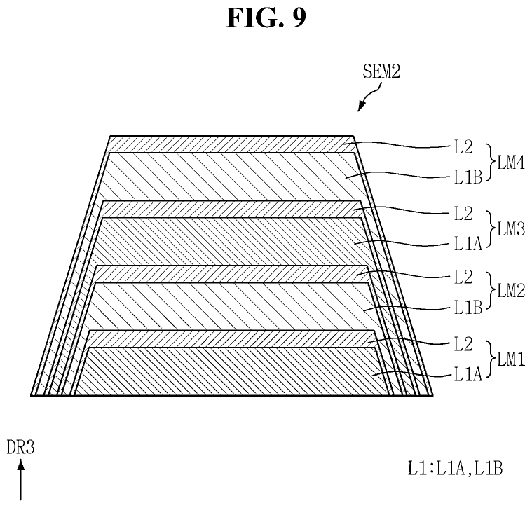

FIG. 9 is a cross-sectional view schematically showing the second semiconductor layer SEM2 of the first light emitting element LE1 according to an embodiment. For example, FIG. 9 schematically shows a cross-sectional shape of a second semiconductor layer SEM2 to which the embodiment(s) described in association with FIG. 8 is/are applied.

Referring to FIGS. 1 to 9, the first layers L1 and the second layers L2 of the second semiconductor layer SEM2 may be alternately disposed in not only the thickness direction (e.g., the third direction DR3) of the first light emitting element LE1, but also in another direction (e.g., a lateral direction) transverse to the thickness direction (e.g., the third direction DR3) of the first light emitting element LE1. For example, the first layers L1 and the second layers L2 of the second semiconductor layer SEM2 may be deposited or otherwise formed on the inclined (or oblique) surface(s) of the second semiconductor layer SEM2, as well as on an upper (e.g., planar surface(s)) of the second semiconductor layer SEM2. In some embodiments, the first layers L1 and the second layers L2 of the second semiconductor layer SEM2 may be deposited or otherwise formed on surfaces of the second semiconductor layer SEM2 corresponding to the r-plane (e.g., a 1012 plane), as well as surfaces corresponding to the c-plane (e.g., a 0001 plane). In some implementations, the first layers L1 and the second layers L2 of the second semiconductor layer SEM2 may be deposited or otherwise formed with a thinner thickness on the oblique surfaces (or in association with the r-plane) than the thickness on the upper surface (or in association with the c-plane).

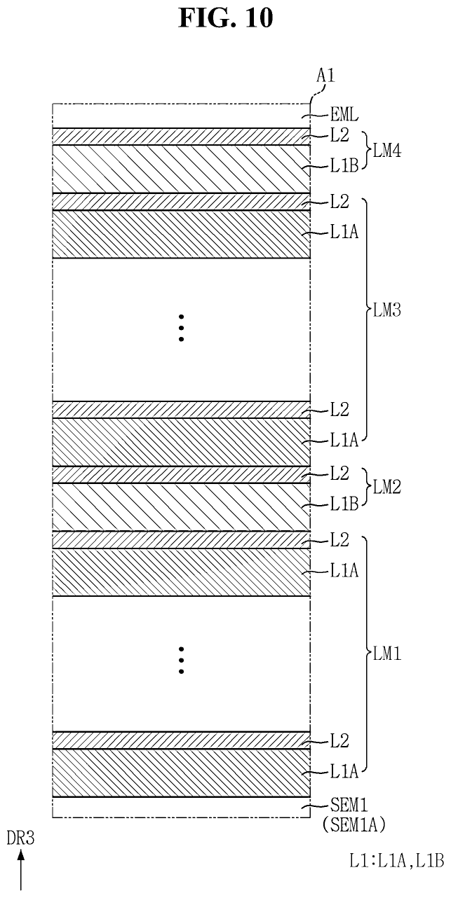

FIG. 10 is a cross-sectional view schematically showing area A1 of FIG. 5 in more detail according to an embodiment. For example, FIG. 10 shows an embodiment similar to the embodiment(s) described in association with FIG. 8 and in relation to the second semiconductor layer SEM2 of the first light emitting element LE1.

Referring to FIGS. 1 to 10, the second semiconductor layer SEM2 of the first light emitting element LE1 may include a larger number of the first layers L1 and the second layers L2. For example, the second semiconductor layer SEM2 of the first light emitting element LE1 may include 10 or more pairs of layers, each pair of layers including a first layer L1 and a second layer L2.

By adjusting the number of the first layers L1 and the second layers L2 included in the laminates, such as the first to fourth laminates LM1 to LM4, the thicknesses and the positions (or heights) of the laminates, and/or the optical characteristics of the light emitting element LE may be adjusted. For example, by adjusting the number of the first layers L1 and the second layers L2 included in each laminate, such as the first to fourth laminates LM1 to LM4, the thickness and the position of each laminate and/or the optical characteristics of the light emitting element LE that are affected by the number of the first layers L1 and the second layers L2 may be adjusted.

In an embodiment, the laminates among the first to fourth laminates LM1 to LM4 having different indium content from one another may include different numbers of the first layers L1 and the second layers L2. In an embodiment, each of the first laminate LM1 and the third laminate LM3 containing indium at a higher content (e.g., the first content) may include a larger number of pairs of layers (e.g., a greater number of the first layers L1A and the second layers L2) than a number of pairs of layers (e.g., a number of the first layers L1B and the second layers L2) included in each of the second laminate LM2 and the fourth laminate LM4 containing indium at a lower content (e.g., the second content). Accordingly, the lattice matching effect of the second semiconductor layer SEM2 of the first light emitting element LE1 may be improved or optimized. Although FIG. 10 shows an embodiment in which each of the second laminate LM2 and the fourth laminate LM4 includes one pair of layers (e.g., one pair of layers including the first layer L1B and the second layer L2), each of the second laminate LM2 and the fourth laminate LM4 may include at least two pairs of layers, each pair of layers including a first layer L1B and a second layer L2.

In an embodiment, each of the first laminate LM1 and the third laminate LM3 may include 6 or more pairs of layers (or 6 cycles) with each pair of layers including a first layer L1A and a second layer L2, and each of the second laminate LM2 and the fourth laminate LM4 may include 5 or fewer pairs of layers (or 5 cycles) with each pair of layers including a first layer L1B and a second layer L2 (or a single first layer L1B and a single second layer L2). In an embodiment, the first laminate LM1 and the third laminate LM3 may include a same number or different numbers of the first layers L1A and the second layers L2 than one another. For example, the first laminate LM1 may include a larger number (e.g., 9 to 21 pairs of layers) of the first layers L1A and the second layers L2, and the third laminate LM3 may include a smaller number (e.g., 9 pairs of layers or less) of the first layers L1A and the second layers L2 than the first laminate LM1. In some embodiments, the second laminate LM2 and the fourth laminate LM4 may include a same number or different numbers of the first layers L1B and the second layers L2 than one another.

In some implementations, the structure, thickness, and/or material (or the content of the material) of the second semiconductor layer SEM2 may be variously changed depending on a target quality and/or optical characteristics of the first light emitting element LE1 including the second semiconductor layer SEM2.

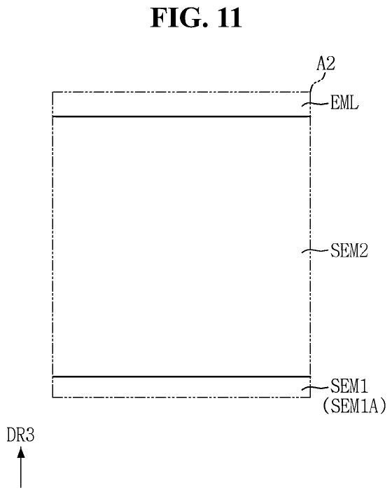

FIG. 11 is a cross-sectional view schematically showing area A2 of FIG. 5 in more detail according to an embodiment. For example, FIG. 11 shows an embodiment of the second semiconductor layer SEM2 of the second light emitting element LE2.

Referring to FIGS. 1 to 11, the second semiconductor layer SEM2 of the second light emitting element LE2 may have a structure different from the structure of the second semiconductor layer SEM2 of the first light emitting element LE1. For example, the second semiconductor layer SEM2 of the second light emitting element LE2 may be formed of a single semiconductor layer. For example, the second semiconductor layer SEM2 of the second light emitting element LE2 may be formed of a single semiconductor layer containing indium and doped with a first conductivity type.

In an embodiment, the second semiconductor layer SEM2 of the third light emitting element LE3 may have a structure that is equivalent (or substantially equivalent) to the structure of the second semiconductor layer SEM2 of the second light emitting element LE2. For example, the second semiconductor layer SEM2 of the third light emitting element LE3 may be formed of a single semiconductor layer containing indium and doped with a first conductivity type.

The indium content of each of the second semiconductor layers SEM2 of the second light emitting element LE2 and the third light emitting element LE3 may be generally uniform or may change (or vary), such as change gradually. For example, each of the second semiconductor layers SEM2 of the second light emitting element LE2 and the third light emitting element LE3 may include indium at a uniform (or substantially uniform) content. In some implementations, the indium content of each of the second semiconductor layers SEM2 of the second light emitting element LE2 and the third light emitting element LE3 may change (e.g., gradually change) (e.g., increase) along the third direction DR3. Accordingly, the quality of the second light emitting element LE2 and the third light emitting element LE3 can be improved.

In some embodiments, the structure of the second semiconductor layer SEM2 of each of the first light emitting element LE1, the second light emitting element LE2, and the third light emitting element LE3 may be differentiated (or formed with a different structure) according to the emission wavelength or the indium content of the respective light emitting layer EML of the corresponding one of the first light emitting element LE1, the second light emitting element LE2, and the third light emitting element LE3. For example, the second semiconductor layer SEM2 of the first light emitting element LE1, in which the light emitting layer EML has a relatively high indium content, and thus, emits a relatively long-wavelength of light (e.g., red light), may be formed having a multilayer structure including multiple first layers L1 and multiple second layers L2. Accordingly, the light emitting layer EML of the first light emitting element LE1 may be formed more smoothly (e.g., with less surface roughness) and/or appropriately, and the optical characteristics (e.g., at least one of the luminous efficiency, the luminance, and the color purity) of the first light emitting element LE1 may be improved. Further, the second semiconductor layer SEM2 of each of the second light emitting element LE2 and the third light emitting element LE3, in which the light emitting layer EML has a relatively low indium content, and thus, emits a relatively short-wavelength of light (e.g., green light or blue light), may be formed having a single layer structure. Accordingly, the second light emitting element LE2 and the third light emitting element LE3 may be easily formed, and the quality of the second light emitting element LE2 and the third light emitting element LE3 may be improved or secured.

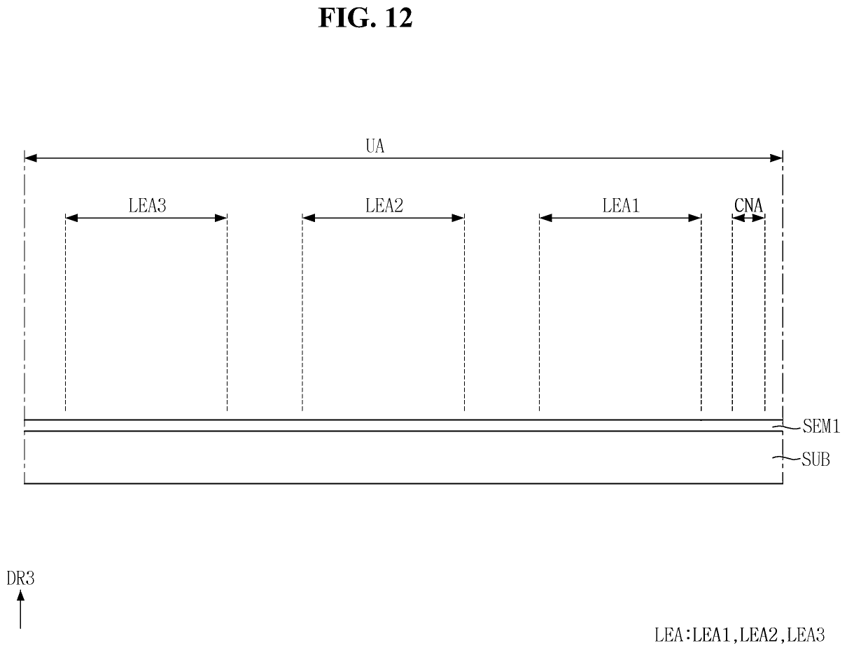

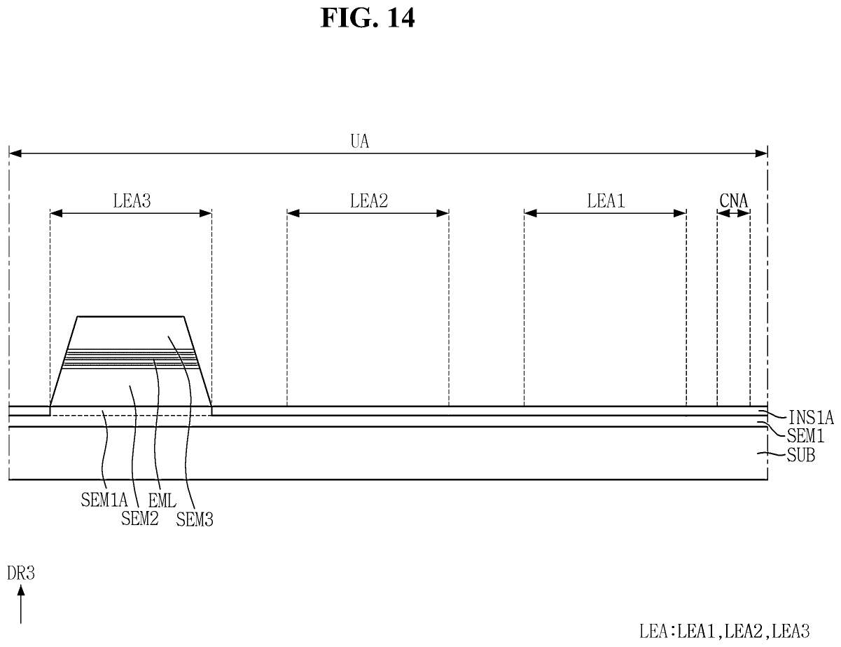

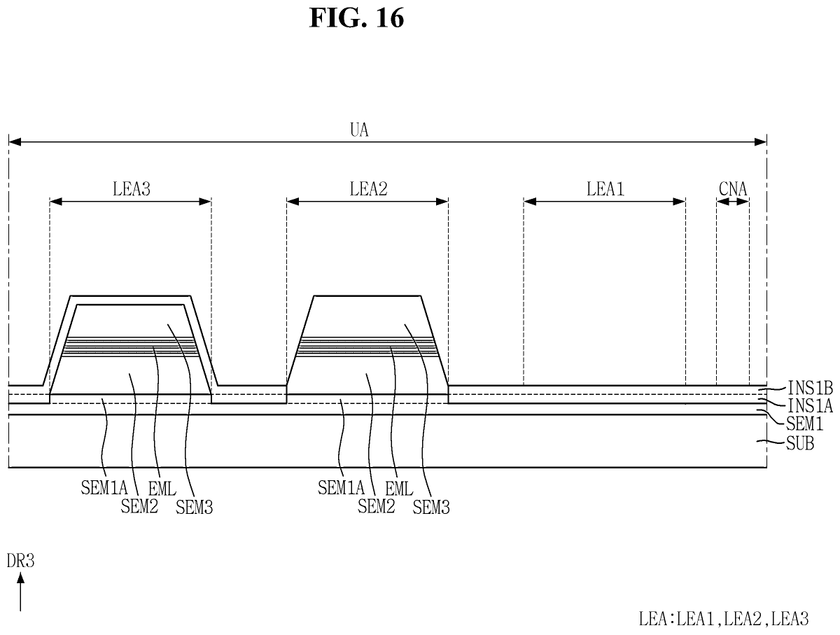

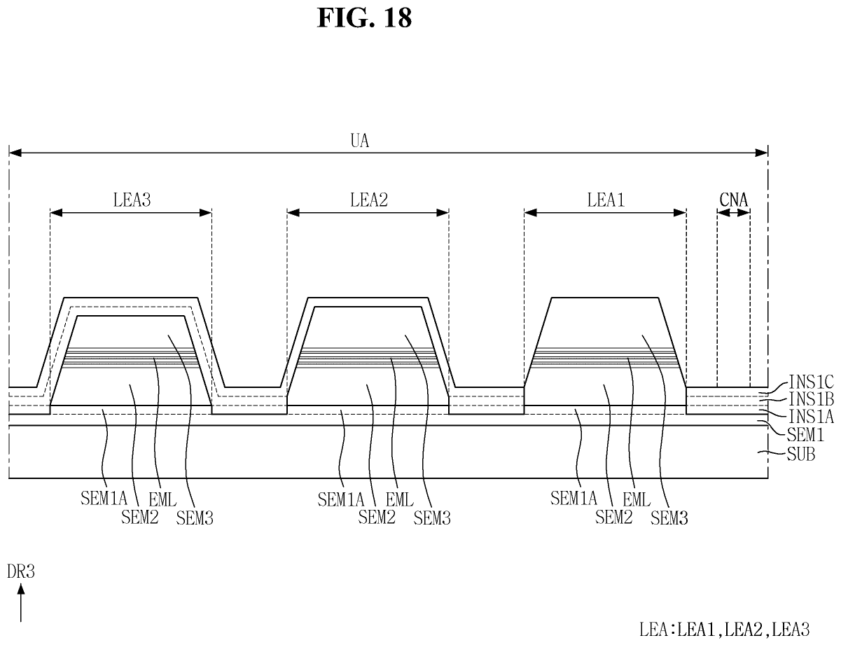

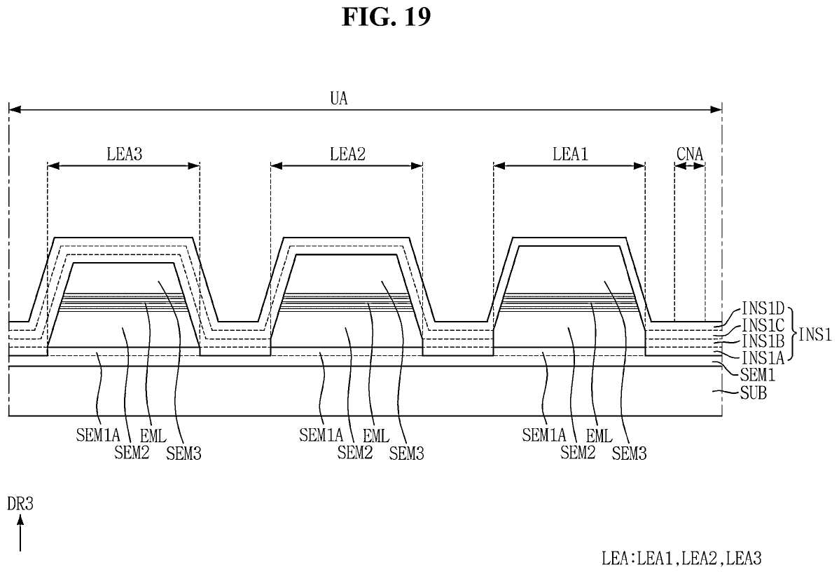

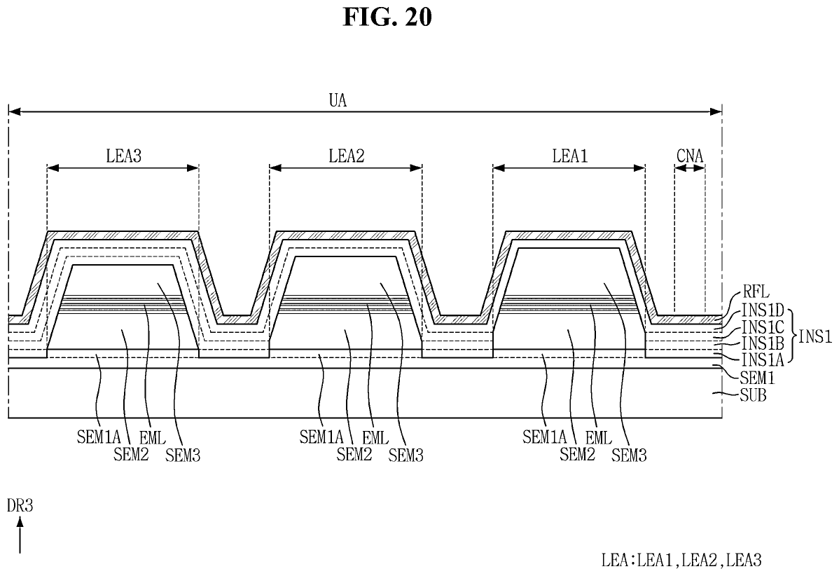

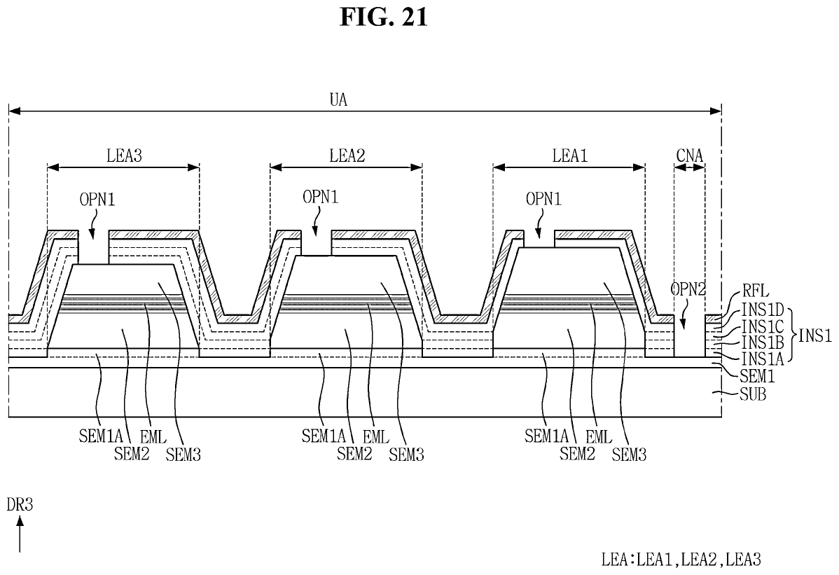

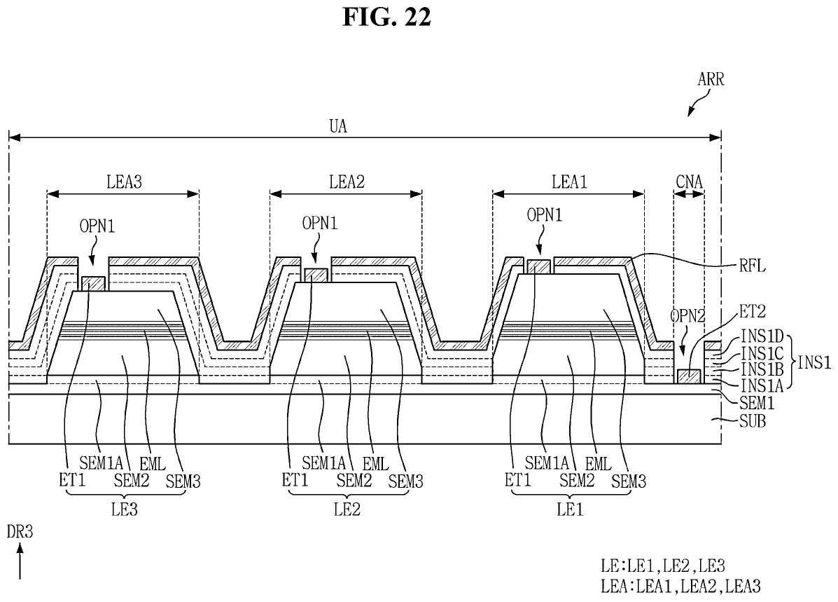

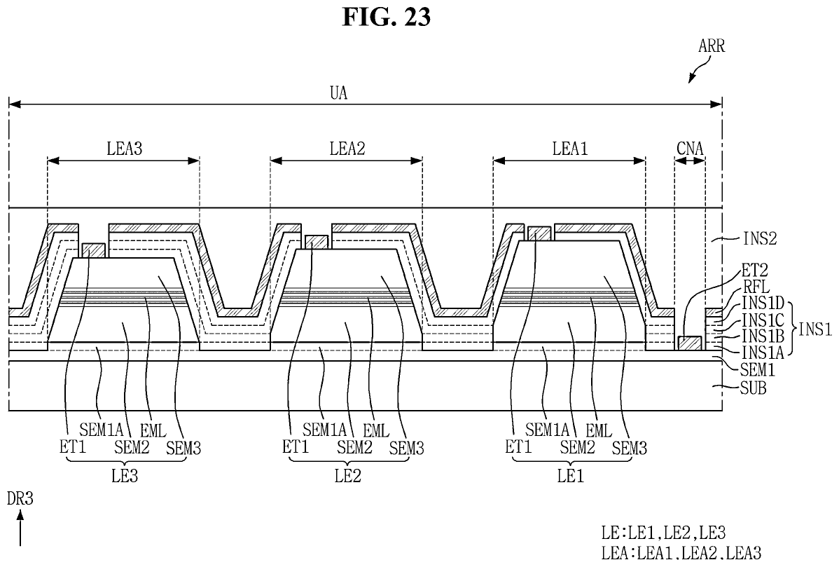

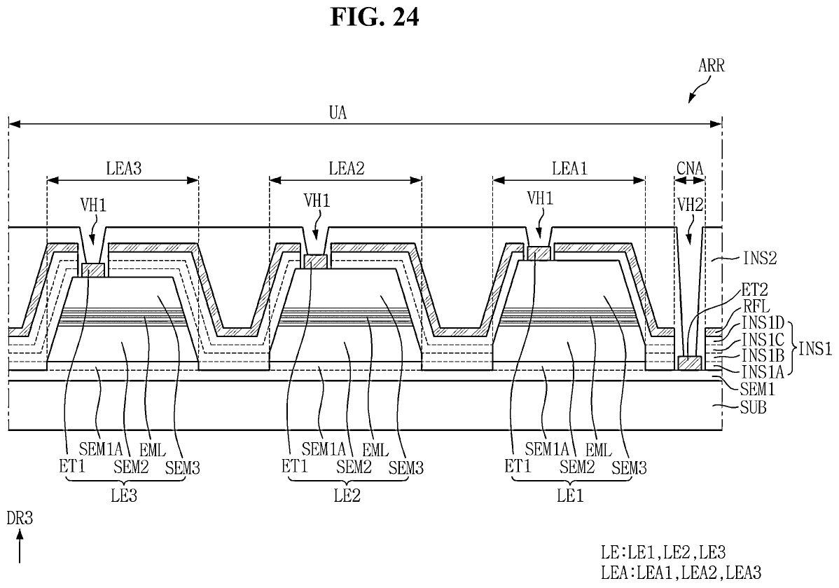

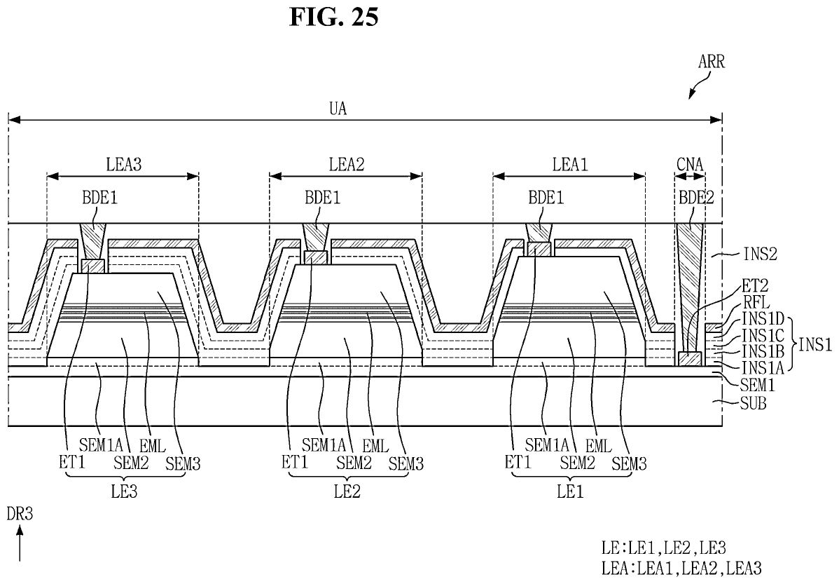

FIGS. 12 to 25 are cross-sectional views schematically showing a light emitting element array ARR at various stages of manufacture according to an embodiment. A method of manufacturing the light emitting array ARR will now be described in association with FIGS. 12 to 22. It is noted that one or more manufacturing steps or processes will be described in association with each of FIGS. 12 to 22, and together, the various manufacturing steps or process may be utilized to form the light emitting element array ARR as at least described in association with FIGS. 1 to 5. In some embodiments, the method may be utilized to form (e.g., sequentially form) the first light emitting element LE1, the second light emitting element LE2, and the third light emitting element LE3 (or the semiconductor layers of the first light emitting element LE1, the second light emitting element LE2, and the third light emitting element LE3) in the unit area UA shown at least in FIG. 5. It is also noted that FIGS. 23 to 25 schematically show the light emitting element array ARR at various stages of manufacture according to an embodiment in which a second insulating layer INS2 and bonding electrodes are further formed as part of the light emitting element array ARR. For example, the light emitting element array ARR according to an embodiment may further include the second insulating layer INS2, one or more first bonding electrodes BDE1, and at least one second bonding electrode BDE2, such as shown in FIG. 25, in addition to the components at least shown in FIG. 5.

Referring to FIGS. 1 to 12, the substrate SUB for manufacturing the light emitting element array ARR may be prepared.

The substrate SUB, which may be a semiconductor substrate suitable for epitaxial growth, may be a semiconductor substrate containing the material exemplified above. For example, the substrate SUB may be at least one of a sapphire substrate, a silicon substrate, and a GaN substrate (e.g., GaN bulk), but is not limited to these examples. The substrate SUB may include the light emitting element areas LEA for forming the light emitting elements LE and the contact area CNA located around (or adjacent to) the light emitting element areas LEA in a view in the third direction DR3.

In a case that the substrate SUB is prepared, the first semiconductor layer SEM1 may be formed (e.g., grown, deposited, and/or the like) on the substrate SUB. In an embodiment, a buffer layer may be formed (e.g., formed first) on the substrate SUB prior to the formation of the first semiconductor layer SEM1, and as such, the first semiconductor layer SEM1 may be formed on the buffer layer, e.g., the buffer layer may be formed between the first semiconductor layer SEM1 and the substrate SUB in the third direction DR3.

The first semiconductor layer SEM1 may be made of at least one of the previously described semiconductor materials, and may be doped with a first conductivity type. For example, the first semiconductor layer SEM1 may be formed of an n-type semiconductor layer including GaN (e.g., n-GaN) doped with an n-type dopant.

Referring to FIGS. 1 to 13, the first mask layer INS1A including an opening corresponding to (or overlapping in the third direction DR3) a first area (for example, exposing the first semiconductor layer SEM1 in the first area, such as the third light emitting element area LEA3) and covering (or overlapping in the third direction DR3) one or more of the other areas (e.g., the second light emitting element area LEA2 and the first light emitting element area LEA1) may be formed on the first semiconductor layer SEM1.

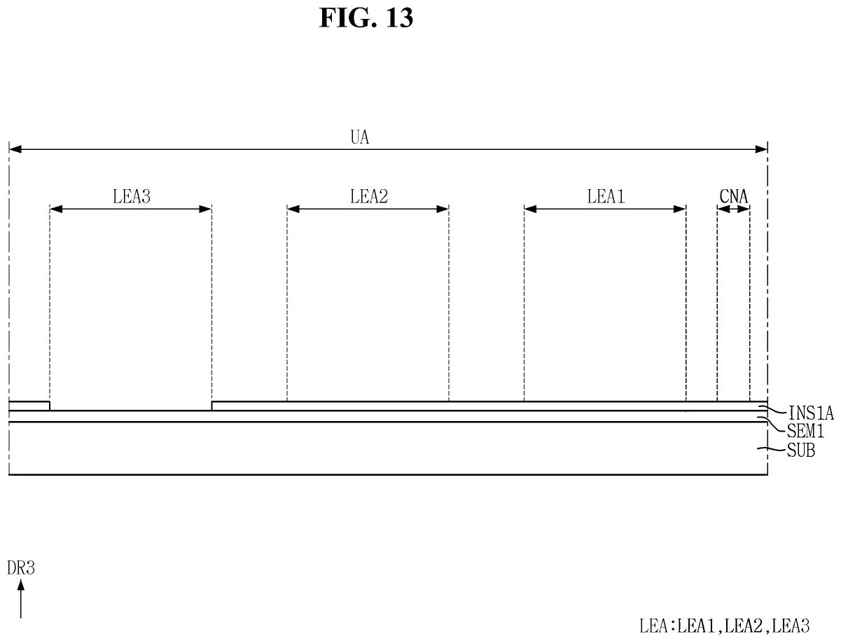

The first area may be an area for forming any one of the first light emitting element LE1, the second light emitting element LE2, and the third light emitting element LE3 to be formed in each unit area UA. For example, in a case that the third light emitting element LE3 is to be formed first among the first light emitting element LE1, the second light emitting element LE2, and the third light emitting element LE3, the first area may be the third light emitting element area LEA3. The formation order of the light emitting elements LE and the first area corresponding to the light emitting element LE that is to be formed first may vary depending on embodiments. In FIGS. 13 to 25, an embodiment in which the first area is the third light emitting element area LEA3 will be described.

The first mask layer INS1A may form the first portion INS1A (or a part of the first portion INS1A) of the first insulating layer INS1 shown in, for instance, FIG. 5. The first mask layer INS1A may be made of at least one of the previously described insulating materials described in association with the first insulating layer INS1, but the material of the first mask layer INS1A is not limited to those example materials.

Referring to FIGS. 1 to 14, the second semiconductor layer SEM2, the light emitting layer EML, and the third semiconductor layer SEM3 may be formed (e.g., sequentially formed) (e.g., grown, regrown, deposited, and/or the like) in the first area (e.g., the third light emitting element area LEA3). In an embodiment, after the seed layer SEM1A containing a same material (e.g., n-GaN including GaN and an n-type dopant) as the first semiconductor layer SEM1 is firstly formed in the first area, the second semiconductor layer SEM2, the light emitting layer EML, and the third semiconductor layer SEM3 may be formed (e.g., sequentially formed) on the seed layer SEM1A in the first area.

The second semiconductor layer SEM2 may be made of a semiconductor material containing indium, and may be doped with a first conductivity type. For example, the second semiconductor layer SEM2 may be formed of an n-type semiconductor layer containing InGaN (e.g., n-InGaN) doped with an n-type dopant, but embodiments are not limited to this example. In an embodiment, in a case of forming the third light emitting element LE3 in the first area, the second semiconductor layer SEM2 of the first area may be formed having a single layer structure.

The light emitting layer EML may include the quantum well layer QWL containing indium. For example, the light emitting layer EML may be formed having a multiple quantum well structure in which the quantum well layers QWL containing indium and the barrier layers BRL are alternately disposed on each other. In an embodiment, the quantum well layer QWL may be made of a semiconductor material (e.g., InGaN) containing indium, and the indium content of the quantum well layer QWL may vary depending on the emission wavelength of the light emitting element LE (e.g., the third light emitting element LE3) formed (or to be formed) in the first area. In an embodiment, in a case that the third light emitting element LE3 formed in the first area is a blue light emitting element that emits blue light, the quantum well layer QWL of the first area may contain indium at a content in a range of about 10% to less than about 20%. In an embodiment, the barrier layer BRL may be made of at least one of the previously described semiconductor materials (e.g., GaN, AlGaN, or GaAlN), but the material is not limited to those examples.

As exemplified above, the third semiconductor layer SEM3 may be made of a semiconductor material containing indium, and may be doped with a second conductivity type. For example, the third semiconductor layer SEM3 may be formed of a p-type semiconductor layer containing InGaN (e.g., p-InGaN) doped with a p-type dopant, but the material and dopant are not limited to these examples. In an embodiment, the third semiconductor layer SEM3 may be formed having a single layer structure, but is not limited to a single layer structure.

Referring to FIGS. 1 to 15, the second mask layer INS1B including an opening corresponding to (or overlapping in the third direction DR3) a second area (for example, exposing the first semiconductor layer SEM1 in the second area, such as the second light emitting element area LEA2), and covering (or overlapping in the third direction DR3) one or more of the other areas (e.g., the third light emitting element area LEA3 and the first light emitting element area LEA1) may be formed on the first mask layer INS1A. The opening corresponding to the second area may also be formed in the first mask layer INS1A. The second mask layer INS1B may cover (or overlap in the third direction DR3) the semiconductor layers (e.g., the first semiconductor layer SEM1 (or the seed layer SEM1A)), the second semiconductor layer SEM2, the light emitting layer EML, and the third semiconductor layer SEM3 of the third light emitting element LE3) formed in the first area.

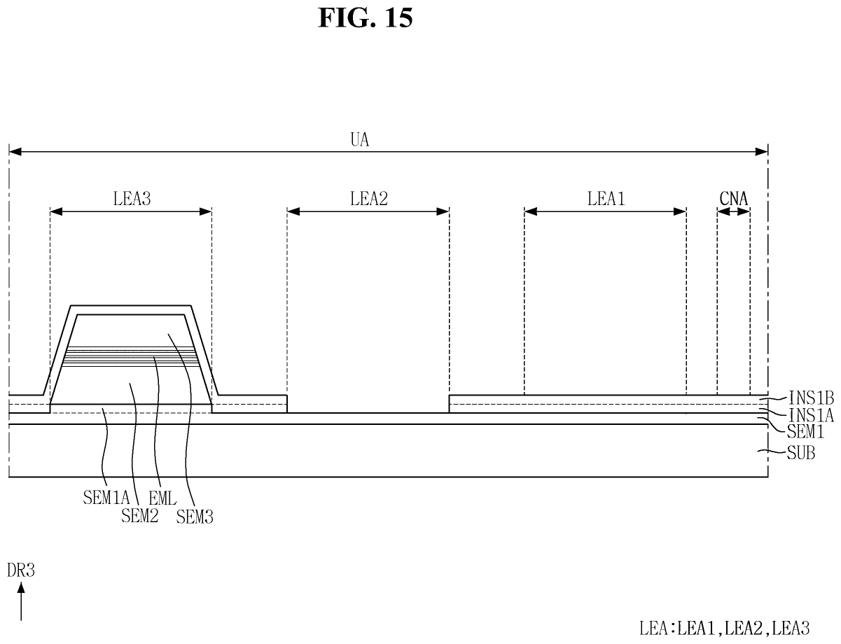

The second area may be an area for forming any one of the first light emitting element LE1, the second light emitting element LE2, and the third light emitting element LE3 to be formed in each unit area UA. For example, in a case that the second light emitting element LE2 is to be formed second among the first light emitting element LE1, the second light emitting element LE2, and the third light emitting element LE3, the second area may be the second light emitting element area LEA2. The formation order of the light emitting elements LE and the second area corresponding to the light emitting element LE that is to be formed second may vary depending on embodiments. In FIGS. 15 to 25, an embodiment in which the second area is the second light emitting element area LEA2 will be described.

The second mask layer INS1B may form the second portion INS1B (or a part of the second portion INS1B) of the first insulating layer INS1 shown in, for example, FIG. 5. In an embodiment, the second mask layer INS1B may be made of at least one of the previously described insulating materials described in association with the first insulating layer INS1 and may be made of a same material as the first mask layer INS1A, but embodiments are not limited to these examples. For example, in some embodiments, the second mask layer INS1B may be made of a material different from the material of the first mask layer INS1A. In some implementations, the first insulating layer INS1 may include a plurality of layers made of different insulating materials.

Referring to FIGS. 1 to 16, the second semiconductor layer SEM2, the light emitting layer EML, and the third semiconductor layer SEM3 may be formed (e.g., sequentially formed) (e.g., grown, regrown, deposited, and/or the like) in the second area (e.g., the second light emitting element area LEA2). In an embodiment, after the seed layer SEM1A containing a same material (e.g., n-GaN) as the first semiconductor layer SEM1 is firstly formed in the second area, the second semiconductor layer SEM2, the light emitting layer EML, and the third semiconductor layer SEM3 may be formed (e.g., sequentially formed) on the seed layer SEM1A in the second area.

The second semiconductor layer SEM2 may be made of a semiconductor material containing indium, and may be doped with a first conductivity type. For example, the second semiconductor layer SEM2 may be formed of an n-type semiconductor layer containing InGaN (e.g., n-InGaN) doped with an n-type dopant, but embodiments are not limited to this example. In an embodiment, in a case of forming the second light emitting element LE2 in the second area, the second semiconductor layer SEM2 of the second area may be formed having a single layer structure.

The light emitting layer EML may include the quantum well layer QWL containing indium. For example, the light emitting layer EML may be formed having a multiple quantum well structure in which the quantum well layers QWL containing indium and the barrier layers BRL are alternately disposed on each other. In an embodiment, the quantum well layer QWL may be made of a semiconductor material (e.g., InGaN) containing indium, and the indium content of the quantum well layer QWL may vary depending on the emission wavelength of the light emitting element LE (e.g., the second light emitting element LE2) formed (or to be formed) in the second area. In an embodiment, in a case that the second light emitting element LE2 formed in the second area is a green light emitting element that emits green light, the quantum well layer QWL of the second area may contain indium at a content in a range of about 20% to less than about 30%. In an embodiment, the barrier layer BRL may be made of at least one of the previously described semiconductor materials (e.g., GaN, AlGaN, or GaAlN), but the material is not limited to those examples.

As exemplified above, the third semiconductor layer SEM3 may be made of a semiconductor material containing indium, and may be doped with a second conductivity type. For example, the third semiconductor layer SEM3 may be formed of a p-type semiconductor layer containing InGaN (e.g., p-InGaN) doped with a p-type dopant, but the material and dopant are not limited to these examples. In an embodiment, the third semiconductor layer SEM3 may be formed having a single layer structure, but is not limited to a single layer structure.

Referring to FIGS. 1 to 17, a third mask layer INS1C including an opening corresponding to (or overlapping in the third direction DR3) a third area (e.g., exposing the first semiconductor layer SEM1 in the third area, such as the first light emitting element area LEA1), and covering (or overlapping in the third direction DR3) one or more of the other areas (e.g., the third light emitting element area LEA3 and the second light emitting element area LEA2) may be formed on the second mask layer INS1B. The opening corresponding to the third area may also be formed in the first mask layer INS1A and the second mask layer INS1B. The third mask layer INS1C may cover (or overlap in the third direction DR3) the semiconductor layers (e.g., the first semiconductor layer SEM1 (or the seed layer SEM1A)), the second semiconductor layer SEM2, the light emitting layer EML, and the third semiconductor layer SEM3 of the second light emitting element LE2) formed in the second area and may cover (or overlap in the third direction DR3) the semiconductor layers (e.g., the first semiconductor layer SEM1 (or the seed layer SEM1A)), the second semiconductor layer SEM2, the light emitting layer EML, and the third semiconductor layer SEM3 of the third light emitting element LE3) formed in the first area.

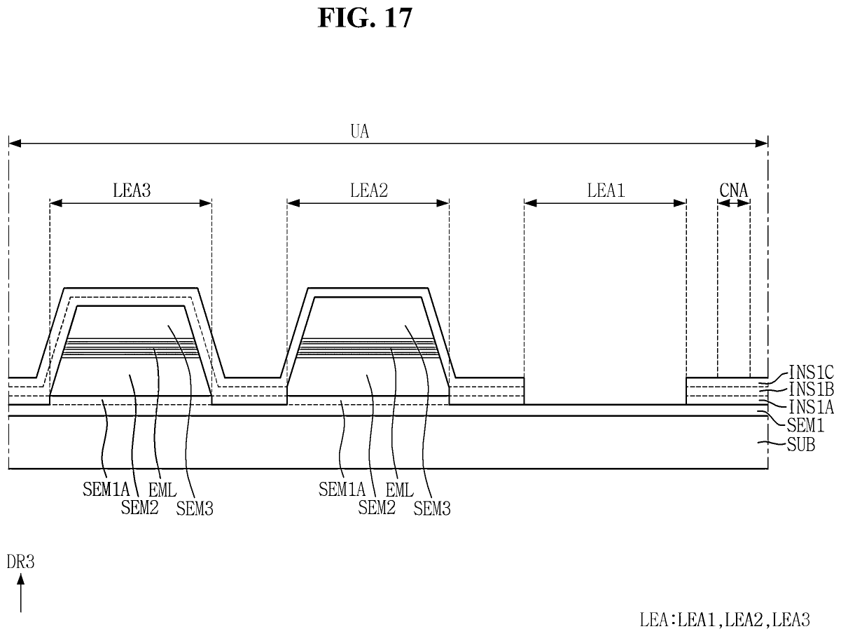

The third area may be an area for forming any one of the first light emitting element LE1, the second light emitting element LE2, and the third light emitting element LE3 to be formed in each unit area UA. For example, in a case that the first light emitting element LE1 is to be formed third among the first light emitting element LE1, the second light emitting element LE2, and the third light emitting element LE3, the third area may be the first light emitting element area LEA1. The formation order of the light emitting elements LE and the third area corresponding to the light emitting element LE that is to be formed third may vary depending on embodiments. In FIGS. 17 to 25, an embodiment in which the third area is the first light emitting element area LEA1 will be described.

The third mask layer INS1C may form the third portion INS1C (or a part of the third portion INS1C) of the first insulating layer INS1 shown in, for example, FIG. 5. In an embodiment, the third mask layer INS1C may be made of at least one of the previously described insulating materials described in association with the first insulating layer INS1 and may be made of a same material as the material of first mask layer INS1A and the second mask layer INS1B, but embodiments are not limited to this example.

Referring to FIGS. 1 to 18, the second semiconductor layer SEM2, the light emitting layer EML, and the third semiconductor layer SEM3 may be formed (e.g., sequentially formed) (e.g., grown, regrown, deposited, and/or the like) in the third area (e.g., the first light emitting element area LEA1). In an embodiment, after the seed layer SEM1A containing a same material (e.g., n-GaN) as the first semiconductor layer SEM1 is firstly formed in the third area, the second semiconductor layer SEM2, the light emitting layer EML, and the third semiconductor layer SEM3 may be formed (e.g., sequentially formed) on the seed layer SEM1A in the third area.

The second semiconductor layer SEM2 may be made of a semiconductor material containing indium, and may be doped with a first conductivity type. For example, the second semiconductor layer SEM2 may be formed of an n-type semiconductor layer containing InGaN (e.g., n-InGaN) doped with an n-type dopant, but embodiments are not limited to this example. In an embodiment, among the light emitting elements LE, the light emitting element LE in which the indium content of the light emitting layer EML is highest, for example, the first light emitting element LE1, may be formed in the third area. In some implementations, the second semiconductor layer SEM2 of the third area may be formed having multiple layers including the first layers L1 containing indium and the second layers L2 stacked alternately with the first layers L1, such as described in association with one or more of FIGS. 7 to 10. For example, the first layers L1 and the second layers L2 may be alternately formed (e.g., grown, re-grown, deposited, and/or the like) on the first semiconductor layer SEM1 (e.g., the seed layer SEM1A) of the third area. Accordingly, the relatively high-quality light emitting layer EML may be formed on the second semiconductor layer SEM2 of the third area.

The light emitting layer EML may include the quantum well layer QWL containing indium. For example, the light emitting layer EML may be formed having a multiple quantum well structure in which the quantum well layers QWL containing indium and the barrier layers BRL are alternately disposed on each other. In an embodiment, the quantum well layer QWL may be made of a semiconductor material (e.g., InGaN) containing indium, and the indium content of the quantum well layer QWL may vary depending on the emission wavelength of the light emitting element LE (e.g., the first light emitting element LE1) formed (or to be formed) in the third area. In an embodiment, in a case that the first light emitting element LE1 formed in the third area is a red light emitting element that emits red light, the quantum well layer QWL of the third area may contain indium at a content in a range of about 30% to about 40%. In an embodiment, the barrier layer BRL may be made of at least one of the previously described semiconductor materials (e.g., GaN, AlGaN, or GaAlN), but the material is not limited to those examples.

As exemplified above, the third semiconductor layer SEM3 may be made of a semiconductor material containing indium, and may be doped with a second conductivity type. For example, the third semiconductor layer SEM3 may be formed of a p-type semiconductor layer containing InGaN (e.g., p-InGaN) doped with a p-type dopant, but the material and dopant are not limited to these examples. In an embodiment, the third semiconductor layer SEM3 may be formed having a single layer structure, but is not limited to a single layer structure.

Referring to FIGS. 1 to 19, a passivation layer INS1D (e.g., a protective layer or a fourth mask layer) may be formed on the third mask layer INS1C. The passivation layer INS1D may be formed entirely (or substantially entirely) on the semiconductor layers and the third mask layer INS1C to cover (or overlap in the third direction DR3) the semiconductor layers formed in the light emitting element areas LEA.

The passivation layer INS1D may form the fourth portion INS1D (or a part of the fourth portion INS1D) of the first insulating layer INS1 shown in, for example, FIG. 5. In an embodiment, the passivation layer INS1D may be formed of at least one of the previously described insulating materials described in association with the first insulating layer INS1 and may be formed of a same material as the first mask layer INS1A, the second mask layer INS1B, and the third mask layer INS1C, but the material of the passivation layer INS1D is not limited to this example.

Referring to FIGS. 1 to 20, the reflective layer RFL may be formed on the first insulating layer INS1 including the first mask layer INS1A, the second mask layer INS1B, the third mask layer INS1C, and the passivation layer INS1D. For example, the reflective layer RFL may be formed entirely (or substantially entirely) on the first insulating layer INS1. The reflective layer RFL may be formed of at least one of the previously described materials described in association with the reflective layer RFL, for example, metal, but the material of the reflective layer RFL is not limited to this example.

Referring to FIGS. 1 to 21, a first opening OPN1 may be formed in the first insulating layer INS1 and the reflective layer RFL in each light emitting element area LEA. Further, a second opening OPN2 may be formed in the first insulating layer INS1 and the reflective layer RFL in the contact area CNA. The first openings OPN1 and the second opening OPN2 may be formed simultaneously with each other, but embodiments are not limited to this example. The first openings OPN1 may expose respective parts of the third semiconductor layers SEM3 formed in the corresponding light emitting element areas LEA. The second opening OPN2 may expose a part of the first semiconductor layer SEM1 formed in the contact area CNA.

Referring to FIGS. 1 to 22, the first electrodes ET1 electrically connected to the third semiconductor layers SEM3 may be respectively formed in the first openings OPN1, and the second electrode ET2 electrically connected to the first semiconductor layer SEM1 may be formed in the second opening OPN2. The first electrodes ET1 and the second electrode ET2 may be formed of at least one of the previously described conductive materials, but the materials of the first electrodes ET1 and the second electrode ET2 are not limited to those examples.

The light emitting element array ARR described in association with at least FIG. 5 and the like may be manufactured through the processes described with reference to FIGS. 12 to 22. In an embodiment, such as shown in FIGS. 23 to 25, the light emitting element array ARR may further include at least one of the second insulating layer INS2 covering the light emitting elements LE, first bonding electrodes BDE1 electrically connected to the first electrodes ET1, and/or the second bonding electrode BDE2 electrically connected to the second electrode ET2.

Referring to FIGS. 1 to 23, the second insulating layer INS2 may be formed on the light emitting elements LE and the reflective layer RFL. In an embodiment, the second insulating layer INS2 may be formed having a single layer structure or a multiple layer structure containing an organic insulating material, and an upper surface of the second insulating layer INS2 may be substantially flat (or planar). For instance, in some embodiments, upper surfaces of the second insulating layer INS2 and the substrate may be parallel (or substantially parallel) with one another.

Referring to FIGS. 1 to 24, a first via hole VH1 may be formed in the second insulating layer INS2 in each light emitting element area LEA. Further, a second via hole VH2 may be formed in the second insulating layer INS2 in the contact area CNA. The first via holes VH1 and the second via hole VH2 may be formed simultaneously, but embodiments are not limited to this example. The first via holes VH1 may respectively expose the first electrodes ET1 correspondingly formed in the light emitting element areas LEA. The second via hole VH2 may expose the second electrode ET2 formed in the contact area CNA.

Referring to FIGS. 1 to 25, a bonding electrode (or wiring) may be respectively formed in each via hole. For example, the respective first bonding electrodes BDE1 may be formed to fill the corresponding first via holes VH1 respectively formed in the light emitting element areas LEA, and the second bonding electrode BDE2 may be formed to fill the second via hole VH2 formed in the contact area CNA. The first bonding electrodes BDE1 and the second bonding electrode BDE2 may be formed by a Damascene process or the like, but embodiments are not limited to this example.

In an embodiment, a subsequent process, such as a chemical mechanical polishing (CMP) process, may be performed after the formation process of at least one of the first bonding electrodes BDE1 and the second bonding electrode BDE2. In an embodiment, in a case of manufacturing an electronic device (e.g., a display device) including the light emitting elements LE, a subsequent process, such as a process of bonding the light emitting elements LE onto (or with) a substrate of the electronic device (e.g., a semiconductor circuit substrate, backplane substrate, or other substrate of a display device) may be performed.

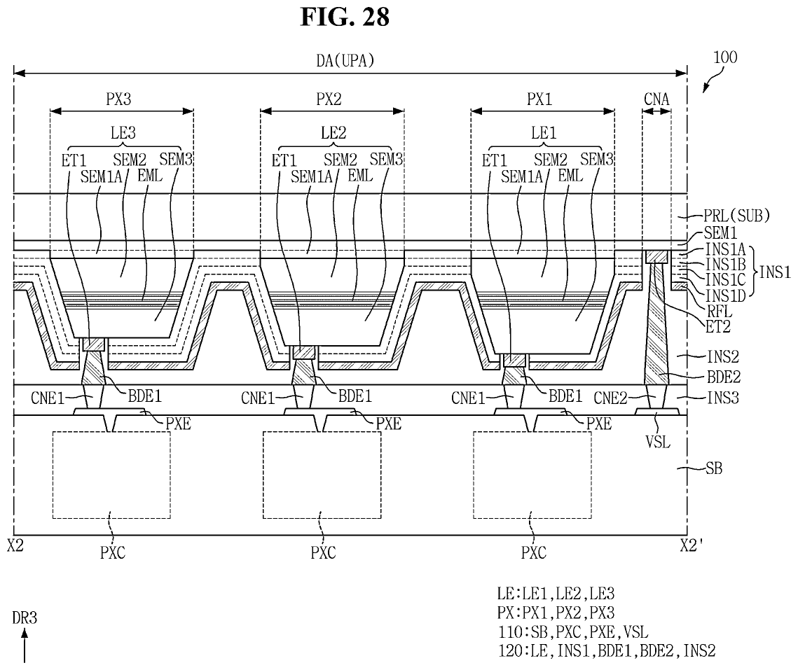

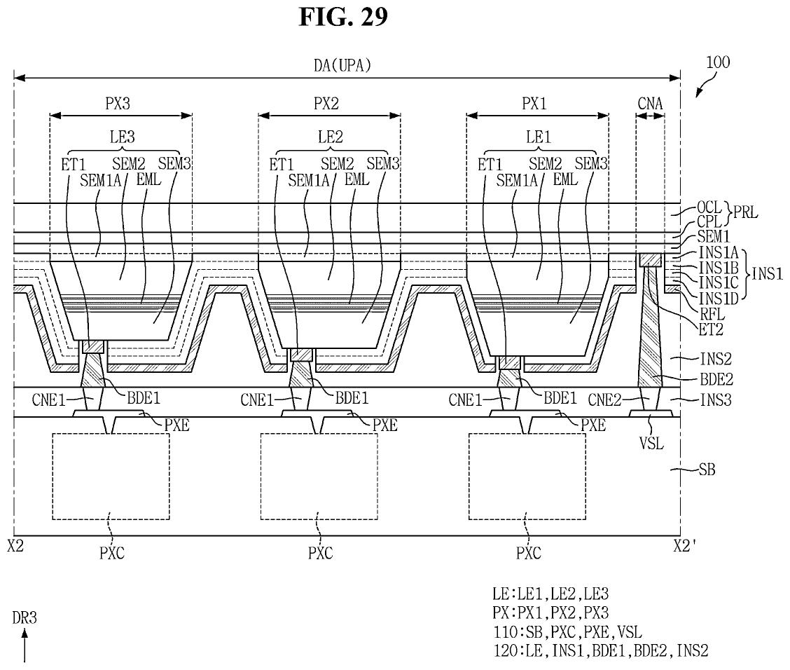

For example, a method of manufacturing a display device using the light emitting element array ARR according to some embodiments may include manufacturing the light emitting element array ARR as previously described or preparing the light emitting element array ARR manufactured according to at least one of the previously described embodiments, and bonding the light emitting elements LE of the light emitting element array ARR onto (or with) a semiconductor circuit substrate (or backplane substrate or other substrate) of a display panel. For example, the method of manufacturing a display device using the light emitting element array ARR manufactured as described in association with, for instance, FIGS. 12 to 25 may further include bonding the light emitting element array ARR onto (or with) a semiconductor circuit substrate (e.g., a semiconductor circuit substrate 110 shown in, for instance, FIGS. 28 and 29) or a backplane (or other) substrate of a display panel in structures illustrated in, for example, FIGS. 28 and 29.

In an embodiment, the substrate SUB may be separated from the light emitting elements LE before or after the bonding process. In some implementations, the substrate SUB may be separated from the light emitting elements LE as part of the bonding process. In some embodiments, the substrate SUB may be embedded in (or otherwise utilized in association with) the electronic device without being separated from the light emitting elements LE.

According to some embodiments, the light emitting elements LE that emit light of different colors may be manufactured on a (e.g., one) substrate SUB. For example, on the substrate SUB, the first light emitting element LE1, the second light emitting element LE2, and the third light emitting element LE3 that emit light of different colors may be formed (e.g., sequentially formed) using, for example, one or more growth and/or regrowth methods. The order of forming the first light emitting element LE1, the second light emitting element LE2, and the third light emitting element LE3 (or the semiconductor layers of the first light emitting element LE1, the second light emitting element LE2, and the third light emitting element LE3) may vary according to embodiments. According to some embodiments, by manufacturing the light emitting elements LE that emit light of different colors on one (or a) substrate SUB, it is possible to increase manufacturing efficiency and reduce manufacturing costs of the light emitting elements LE and an electronic device (e.g., a display device) including the light emitting elements LE.

In an embodiment, the light emitting element array ARR may be formed on the substrate SUB in a size and/or arrangement structure corresponding to a pixel arrangement structure of a display device or the like, which will use the light emitting elements LE, or a size, arrangement structure, arrangement interval, and/or the like of the light emitting elements LE provided in the pixels. Accordingly, the bonding process(es) and the like may be simplified or facilitated, and the manufacturing efficiency of the display device including the light emitting elements LE may be further improved. In some implementations, it is possible to more easily manufacture a relatively high-resolution display device.

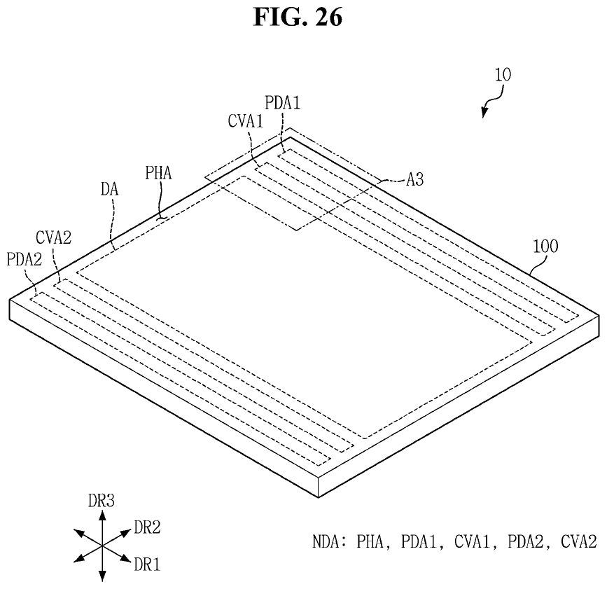

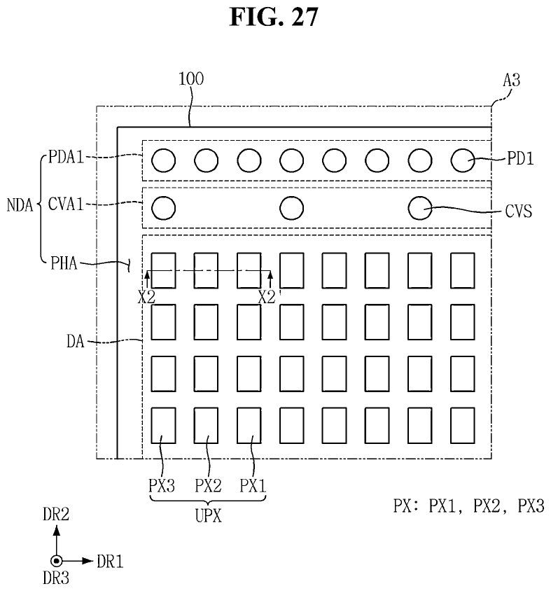

FIG. 26 is a perspective view schematically illustrating a display device 10 according to an embodiment. FIG. 27 is a plan view schematically showing an example of area A3 of FIG. 26 according to an embodiment.

Referring to FIGS. 26 and 27, the display device 10 according to an embodiment may include a display panel 100 having a display area DA and a non-display area NDA.

The display panel 100 may have a quadrilateral planar shape having long sides in the first direction DR1 and short sides in the second direction DR2. In FIGS. 26 and 27, the first direction DR1 may refer to a horizontal direction (or vertical direction) of the display panel 100, and the second direction DR2 may refer to a vertical direction (or horizontal direction) of the display panel 100. The third direction DR3 may refer to a thickness direction or a height direction of the display panel 100. However, the planar shape of the display panel 100 is not limited to this example, and the display panel 100 may have a different planar shape. For example, the display panel 100 may have at least one of a polygonal planar shape other than a quadrilateral planar shape, a circular planar shape, an elliptical planar shape, an oval planar shape, and an irregular (or freeform) planar shape.

The display area DA may be an area where an image is displayed, and the non-display area NDA may be an area where an image is not displayed. In an embodiment, the planar shape of the display area DA may follow (or may be similar to) the planar shape of the display panel 100, but embodiments are not limited to this example. FIG. 26 illustrates an embodiment in which the display area DA has a quadrilateral planar shape. The display area DA may be disposed in a central area of the display panel 100. The non-display area NDA may be disposed adjacent to (e.g., at least partially around) the display area DA in a view in the third direction DR3. For example, the non-display area NDA may surround the display area DA in a view in the third direction DR3.

The display panel 100 may include a plurality of pixels PX arranged in the display area DA. For example, the display panel 100 may include first pixels PX1 emitting light of the first color, second pixels PX2 emitting light of the second color, and third pixels PX3 emitting light of the third color. In an embodiment, the first color may be red, the second color may be green, and the third color may be blue, but the colors are not limited to this example. At least one first pixel PX1, at least one second pixel PX2, and at least one third pixel PX3 adjacent to each other may constitute a unit pixel UPX capable of emitting light of various colors. For example, the first pixel PX1, the second pixel PX2, and the third pixel PX3, which are disposed adjacent to each other in a Kth (where K is a natural number) row of the display area DA, may constitute one unit pixel UPX. The number, type, and/or arrangement structure of the pixels PX constituting the unit pixel UPX may vary depending on embodiments.

Each pixel PX may include at least one light emitting element LE. For example, each pixel PX may include a single light emitting element LE or may include multiple light emitting elements LE that emit light of a same color.

In an embodiment, the pixels PX may include the light emitting elements LE that emit light of different colors. For example, the first pixels PX1, the second pixels PX2, and the third pixels PX3 may include the light emitting elements LE that emit light of the first color, light of the second color, and light of the third color, respectively. However, embodiments are not limited to this example. For example, the first pixels PX1, the second pixels PX2, and the third pixels PX3 may include the light emitting elements LE that emit light of a same color, and light conversion patterns (e.g., wavelength conversion patterns including, for instance, quantum dots) and/or color filters may be disposed in the emission areas of the first pixels PX1, the second pixels PX2, and/or the third pixels PX3 to convert or control the color of light emitted from the light emitting elements LE provided in the respective pixels PX.

In an embodiment, the pixels PX may include the light emitting elements LE according to at least one of the aforementioned embodiments. For example, each first pixel PX1 may include one or more of the first light emitting elements LE1 that include the second semiconductor layer SEM2 having a multilayer structure. Further, each second pixel PX2 may include one or more of the second light emitting elements LE2 that include the second semiconductor layer SEM2 having a single layer structure, and each third pixel PX3 may include one or more of the third light emitting elements LE3 that include the second semiconductor layer SEM2 having a single layer structure.

In an embodiment, the pixels PX may be arranged in the display area DA in a matrix form, a stripe form, or any other form or pattern. The sizes of the pixels PX (or the emission areas of the pixels PX) may be substantially equivalent or different from each other.

In an embodiment, the pixels PX may have a quadrilateral planar shape, such as a rectangular planar shape or a rhombic planar shape, but embodiments are not limited to these examples. For example, the pixels PX may have at least one of another polygonal planar shape (e.g., a hexagonal planar shape, a diamond planar shape, etc.), a circular planar shape, an elliptical planar shape, an oval planar shape, a freeform planar shape, and any other planar shape.

The non-display area NDA may include a first common voltage supply area CVA1, a second common voltage supply area CVA2, a first pad area PDA1, a second pad area PDA2, and a peripheral area PHA.

The first common voltage supply area CVA1 may be disposed between the first pad area PDA1 and the display area DA in a view in, for instance, the third direction DR3. The second common voltage supply area CVA2 may be disposed between the second pad area PDA2 and the display area DA in a view in, for instance, the third direction DR3. Each of the first common voltage supply area CVA1 and the second common voltage supply area CVA2 may include common electrode connection portions CVS that are electrically connected to a common electrode of the pixels PX, a second pixel power line, and/or the like. A second pixel voltage (e.g., a common voltage) may be supplied to the pixels PX through the common electrode connection portions CVS.

The common electrode connection portions CVS may be disposed in a common voltage supply area (e.g., the first common voltage supply area CVA1 and/or the second common voltage supply area CVA2) of the non-display area NDA. The common electrode connection portions CVS may include a conductive material (e.g., a metal material, such as aluminum (Al)). FIGS. 26 and 27 schematically illustrate the display device 10 in which the common electrode connection portions CVS are located in the non-display area NDA, but embodiments are not limited to this example. For example, the common electrode connection portions CVS may be located in the display area DA, the non-display area NDA, or both the display area DA and the non-display area NDA.

The common electrode connection portions CVS of the first common voltage supply area CVA1 may be electrically connected to any one of the first pads PD1 of the first pad area PDA1. For example, the common electrode connection portions CVS of the first common voltage supply area CVA1 may receive a second pixel voltage (e.g., a common voltage) from any one of the first pads PD1 of the first pad area PDA1.

The first pads PD1 may be disposed in the first pad area PDA1. The first pads PD1 may be electrically connected to a circuit board (not shown) through at least one conductive connection member (e.g., wiring, transmission line, etc.). For example, the first pads PD1 may be electrically connected to a circuit pad provided on a circuit board through at least one wire.

The common electrode connection portions CVS of the second common voltage supply area CVA2 may be electrically connected to any one of second pads of the second pad area PDA2. For example, the common electrode connection portions CVS of the second common voltage supply area CVA2 may receive a second pixel voltage (e.g., a common voltage) from any one of the second pads of the second pad area PDA2. In an embodiment, the display panel 100 may not include the second common voltage supply area CVA2.

The first pad area PDA1 may be disposed on one (or a) side (e.g., an upper side) of the display panel 100 in a view in the third direction DR3. The first pad area PDA1 may include the first pads PD1, which may be electrically connected to an external circuit board.

The second pad area PDA2 may be disposed on one (or a) side (e.g., a lower side) of the display panel 100 in a view in the third direction DR3. The second pad area PDA2 may include the second pads, which may be electrically connected to an external circuit board. In an embodiment, the display panel 100 may not include the second pad area PDA2.

The second pads may be disposed in the second pad area PDA2 of the non-display area NDA. The second pads may be electrically connected to a circuit board (not shown) through at least one conductive connection member, such as a wire, transmission line, and/or the like. For example, the second pads may be electrically connected to the circuit pads provided on the circuit board through one or more wires.

The peripheral area PHA may be an area of the non-display area NDA except for the first common voltage supply area CVA1, the second common voltage supply area CVA2, the first pad area PDA1, and the second pad area PDA2. The peripheral area PHA may at least partially surround (or circumscribe) not only the display area DA, but also the first common voltage supply area CVA1, the second common voltage supply area CVA2, the first pad area PDA1, and the second pad area PDA2 in a view in the third direction DR3. In some implementations, the peripheral area PHA may be disposed between at least two of the display area DA, the first common voltage supply area CVA1, the second common voltage supply area CVA2, the first pad area PDA1, and the second pad area PDA2 in a view in the third direction DR3.

FIG. 28 is a cross-sectional view schematically illustrating the display panel 100 according to an embodiment. FIG. 29 is a cross-sectional view schematically illustrating the display panel 100 according to an embodiment. For example, FIGS. 28 and 29 schematically illustrate embodiments of a cross-section of the display panel 100 taken along sectional line X2-X2′ of FIG. 27. The cross-sections illustrated in FIGS. 28 and 29 include schematic depictions of the first pixel PX1, the second pixel PX2, and the third pixel PX3 located in a unit pixel UPA of the display area DA. The unit pixel UPA may correspond with the previously described unit pixel UPX. FIGS. 28 and 29 schematically show different embodiments with respect to the structure of a protective layer PRL.

FIGS. 28 and 29 schematically illustrate embodiments in which the display device 10 is a light emitting diode on silicon (LEDoS), in which light emitting diodes are formed as the light emitting elements LE on the semiconductor circuit substrate 110 formed by at least one semiconductor process using a silicon wafer. However, a device including the light emitting elements LE is not limited to this example. For example, the light emitting elements LE (or the light emitting element array ARR including the light emitting elements LE) manufactured according to one or more of the previously described embodiments may be applied to (or used in association with) display devices of different types and/or structures, or may be applied to (or used in association with) devices of different types and/or structures, such as lighting devices.

Referring to FIGS. 1 to 29, the display panel 100 may include the semiconductor circuit substrate 110 (or backplane substrate or other substrate) and a light emitting element layer 120.

In an embodiment, the display panel 100 may further include an additional component (or element) between the semiconductor circuit substrate 110 and the light emitting element layer 120 in, for instance, the third direction DR3. For example, the display panel 100 may further include connection electrodes (e.g., one or more first connection electrodes CNE1 and one or more second connection electrodes CNE2) that are disposed on the semiconductor circuit substrate 110 and electrically connect respective pixel circuits PXC, pixel electrodes PXE, and at least one second pixel power line VSL of the semiconductor circuit substrate 110 to the corresponding light emitting elements LE of the light emitting element layer 120, and a third insulating layer INS3 that is disposed in the vicinity of at least one of the first connection electrodes CNE1 and the second connection electrodes CNE2 and covers (or overlaps in the third direction DR3) the semiconductor circuit substrate 110.

In an embodiment, the display panel 100 may further include at least one additional component (or element) provided on the light emitting element layer 120. For example, the display panel 100 may further include the protective layer PRL disposed on the light emitting element layer 120. The display panel 100 may further include a light output structure (e.g., a lens, a window, and/or the like) disposed on the protective layer PRL.

The semiconductor circuit substrate 110 may include the display area DA in which the pixel circuits PXC of the pixels PX are formed. The semiconductor circuit substrate 110 may further include the non-display area NDA described in association with FIGS. 26 and 27. In some embodiments, the semiconductor circuit substrate 110 may further include the common electrode connection portions CVS, the first pads PD1, and/or the second pads disposed in the non-display area NDA.

The semiconductor circuit substrate 110 may include a base substrate SB, the pixel circuits PXC disposed or formed on the base substrate SB, and the pixel electrodes PXE (or first bonding pads) electrically connected to the respective pixel circuits PXC. The semiconductor circuit substrate 110 may further include wires (or other circuit components) electrically connected to the pixels PX. For example, the semiconductor circuit substrate 110 may further include signal lines and power lines (e.g., a first pixel power line to which a first pixel voltage is applied) electrically connected to the pixel circuits PXC, and the second pixel power line VSL to which a second pixel voltage may be applied.

In an embodiment, the semiconductor circuit substrate 110 may be formed through at least one semiconductor process using a silicon wafer. For example, the base substrate SB may be a silicon wafer. In an embodiment, the base substrate SB may be made of monocrystalline silicon. It is contemplated, however, that any other suitable base substrate SB may be utilized.

The pixel circuits PXC may be disposed on the semiconductor circuit substrate 110 to correspond with (e.g., overlap in the third direction DR3) the regions where the respective pixels PX are disposed or formed. In an embodiment, each of the pixel circuits PXC may include a complementary metal oxide semiconductor (CMOS) circuit formed using at least one semiconductor process. In an embodiment, each of the pixel circuits PXC may include at least one transistor and at least one capacitor formed using at least one semiconductor process. FIGS. 28 and 29 schematically illustrate locations of the pixel circuits PXC provided in (or as part of) the first pixel PX1, the second pixel PX2, and the third pixel PX3 as an example of elements provided on the semiconductor circuit substrate 110.

The pixel electrodes PXE may be disposed on the respective pixel circuits PXC. The pixel electrodes PXE may be electrically connected to the respective pixel circuits PXC. For example, the pixel circuit PXC of each pixel PX may be electrically connected to the pixel electrode PXE of the corresponding pixel PX. The pixel electrode PXE may receive a first pixel voltage (e.g., an anode voltage) from the pixel circuits PXC, respectively.

In an embodiment, the pixel electrodes PXE may be formed integrally with the respective pixel circuits PXC and/or the pixel electrodes PXE may be integral with the respective pixel circuits PXC. For example, the pixel electrodes PXE may be exposed electrodes that protrude from top surfaces of the respective pixel circuits PXC.

The pixel electrodes PXE may include at least one conductive material. For example, the pixel electrodes PXE may include, but not are limited to, at least one of copper (Cu), titanium (Ti), silver (Ag), magnesium (Mg), aluminum (Al), platinum (Pt), lead (Pd), gold (Au), nickel (Ni), neodymium (Nd), iridium (Ir), chromium (Cr), lithium (Li), and calcium (Ca).

The pixel electrodes PXE may be electrically connected to the respective light emitting elements LE through the first connection electrodes CNE1, respectively. For example, the pixel electrode PXE of the first pixel PX1 may be electrically connected to the first light emitting element LE1 of the first pixel PX1 through the first connection electrode CNE1 provided in (or as part of) the first pixel PX1. The pixel electrode PXE of the second pixel PX2 may be electrically connected to the second light emitting element LE2 of the second pixel PX2 through the first connection electrode CNE1 provided in (or as part of) the second pixel PX2. The pixel electrode PXE of the third pixel PX3 may be electrically connected to the third light emitting element LE3 of the third pixel PX3 through the first connection electrode CNE1 provided in (or as part of) the third pixel PX3.

The second pixel power line VSL may be disposed in the contact area CNA. The second pixel power line VSL may be electrically connected to the second connection electrode CNE2, and may be electrically connected to the second electrode ET2 electrically connected to the first semiconductor layer SEM1 of the light emitting elements LE through the second connection electrode CNE2.

The third insulating layer INS3 may be disposed on the semiconductor circuit substrate 110. The third insulating layer INS3 may include openings corresponding to the first connection electrodes CNE1 and the second connection electrode CNE2. For example, the third insulating layer INS3 may surround (or contact, e.g., directly contact) the side (or peripheral or lateral) surfaces of the first connection electrodes CNE1 and the second connection electrode CNE2 in a view in a direction perpendicular to the third direction DR3.

The third insulating layer INS3 may include at least one insulating material and may have a single layer or multilayer structure. In an embodiment, the third insulating layer INS3 may include an inorganic insulating material (e.g., at least one of silicon oxide (SiOₓ), silicon nitride (SiNₓ), aluminum oxide (AlₓO_{y}), titanium oxide (TiₓO_{y}), hafnium oxide (HfOₓ), and any other inorganic insulating material), but is not limited to these examples.

The first connection electrodes CNE1 and the second connection electrode CNE2 may include a conductive metal. For example, the first connection electrodes CNE1 and the second connection electrode CNE2 may include at least one of gold (Au), copper (Cu), tin (Sn), titanium (Ti), aluminum (Al), and silver (Ag). The first connection electrodes CNE1 and the second connection electrode CNE2 may serve as a bonding metal (or bonding structure) for physically and/or electrically connecting and/or adhering the semiconductor circuit substrate 110 to the light emitting element layer 120.

The light emitting element layer 120 may include the second electrode ET2 and the light emitting elements LE of the pixels PX. In an embodiment, the light emitting element layer 120 may be formed using the light emitting element array ARR according to at least one of the embodiments described in association with FIG. 5 and/or the like, or the light emitting element array ARR manufactured according to at least one of the embodiments described in association with FIGS. 12 to 25. For example, the light emitting element array ARR (or the light emitting elements LE of the light emitting element array ARR) as described in association with FIG. 25 may be bonded onto (or with) the first connection electrodes CNE1 and second connection electrode CNE2 to form the light emitting element layer 120 of the display panel 100.

The light emitting elements LE may have a structure as described in association with at least one of aforementioned embodiments. For example, each of the light emitting elements LE may include the first semiconductor layer SEM1 doped with a first conductive type, the second semiconductor layer SEM2 that is disposed on one (or a) surface (e.g., a lower surface as shown in FIG. 28) of the first semiconductor layer SEM1, is doped with a first conductive type, and contains indium; the light emitting layer EML that is disposed on one (or a) surface of the second semiconductor layer SEM2 and contains indium; and the third semiconductor layer SEM3 that is disposed on one (or a) surface of the light emitting layer EML and doped is with a second conductive type. In an embodiment, each of the light emitting elements LE may further include at least one of the first electrode ET1 electrically connected to the third semiconductor layer SEM3 and the second electrode ET2 electrically connected to the first semiconductor layer SEM1.

The first electrodes ET1 of the light emitting elements LE may be physically and/or electrically connected to the first connection electrodes CNE1 through the first bonding electrodes BDE1. The second electrode ET2 of the light emitting elements LE may be physically and/or electrically connected to the second connection electrode CNE2 through the second bonding electrode BDE2. In an embodiment, the light emitting elements LE may be formed on one (or a) manufacturing substrate (e.g., the substrate SUB shown in, for instance, FIG. 5), and may be provided in the display panel 100 and electrically connected with the first semiconductor layer SEM1.

In some embodiments, the indium content of the light emitting layer EML of the first light emitting element LE1 may be higher than the indium content of the light emitting layers EML of the second light emitting element LE2 and the third light emitting element LE3. In some implementations, the second semiconductor layer SEM2 of the first light emitting element LE1 may be formed having multiple layers including the first layers L1 containing indium and the second layers L2 disposed between the first layers L1. The second semiconductor layer SEM2 of at least one of the second light emitting element LE2 and the third light emitting element LE3 may be formed having a single layer containing indium.

At least because the light emitting element array ARR (or light emitting elements LE) may be bonded onto (or with) the semiconductor circuit substrate 110, the pixels PX including the light emitting elements LE and the pixel circuits PXC may be formed. For example, the first pixel PX1 may include the first light emitting element LE1 and the pixel circuit PXC electrically connected to the first light emitting element LE1. The second pixel PX2 may include the second light emitting element LE2 and the pixel circuit PXC electrically connected to the second light emitting element LE2. The third pixel PX3 may include the third light emitting element LE3 and the pixel circuit PXC electrically connected to the third light emitting element LE3.

In an embodiment, the substrate SUB used as a manufacturing substrate for manufacturing the light emitting elements LE may be substantially transparent, and the light emitting elements LE may not be separated from the substrate SUB. For example, as shown in FIG. 28, the substrate SUB may be provided in or as part of the display panel 100 together with the light emitting elements LE to form the protective layer PRL.

In some embodiments, the substrate SUB may be separated from the light emitting elements LE before, after, or during the bonding process, and a separate protective layer PRL may be disposed (or formed) on the light emitting elements LE. For example, as shown in FIG. 29, the separate protective layer PRL may be disposed (or formed) on the first semiconductor layer SEM1 of the light emitting elements LE that are separated from the substrate SUB. In an embodiment, the protective layer PRL may include at least one of a capping layer CPL and an overcoat layer OCL.

The capping layer CPL may be entirely (or substantially entirely) disposed in the display area DA to cover (or overlap in the third direction DR3) the light emitting elements LE. In an embodiment, the capping layer CPL may include an inorganic material.

The overcoat layer OCL may be entirely (or substantially entirely) disposed on the capping layer CPL. The overcoat layer OCL may contain a material that can protect the light emitting element layer 120 and/or the like.

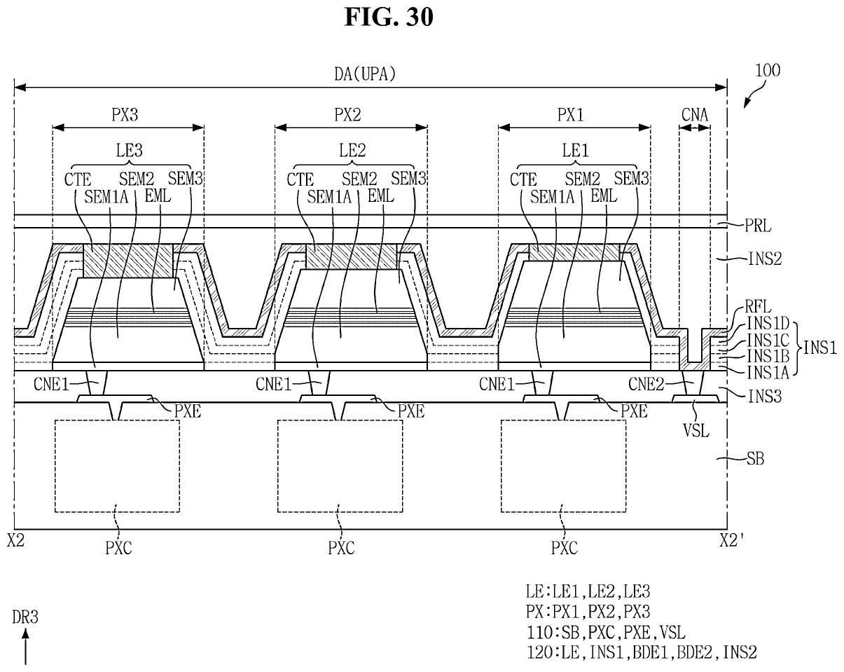

FIG. 30 is a cross-sectional view schematically illustrating the display panel 100 according to an embodiment. For example, FIG. 30 schematically shows an embodiment of a cross-section of the display panel 100 taken along sectional line X2-X2′ of FIG. 27 according to an embodiment, which is different from the embodiments described in association with FIGS. 28 and 29.

Referring to FIGS. 1 to 30, the display panel 100 may include the light emitting element layer 120 formed using the light emitting element array ARR according to at least one of the embodiments described in association with FIG. 6. For example, the light emitting elements LE may include transparent electrodes CTE disposed on the third semiconductor layers SEM3.

The transparent electrodes CTE may be electrically connected to the second pixel power line VSL in the contact area CNA through the reflective layer RFL. In some implementations, the third semiconductor layers SEM3 of the light emitting elements LE may be commonly electrically connected to the second pixel power line VSL.

In an embodiment, a part of the light emitting element array ARR described in association with FIG. 6, in which the first semiconductor layers SEM1 of the light emitting elements LE are integrally formed (or integral) with one another (e.g., the lower part of the first semiconductor layer SEM1 shown in, for example, FIG. 6), may be separated from the light emitting elements LE before the light emitting elements LE are bonded onto (or with) the semiconductor circuit substrate 110, and only the seed layer SEM1A of each light emitting element LE may remain in each light emitting element LE as a part of the first semiconductor layer SEM1. The seed layer SEM1A may be electrically connected to the respective pixel circuits PXC of the pixels PX. For example, the seed layer SEM1A of each light emitting element LE may be disposed on a corresponding first connection electrode CNE1 of a respective pixel PX as the first semiconductor layer SEM1 of that corresponding light emitting element LE, and may be electrically connected to the pixel electrode PXE of a corresponding pixel PX through the respective first connection electrode CNE1. In some embodiments, the light emitting elements LE may be bonded onto (or with) the first connection electrodes CNE1 and at least a part of the seed layer SEM1A may also be separated from the light emitting elements LE. For instance, at least a portion of the seed layer SEM1A may be removed along with the first semiconductor layer SEM1 prior to a remaining portion of the seed layer SEM1A being bonded onto (or with) the first connection electrodes CNE1.

The second insulating layer INS2 may be disposed on the light emitting elements LE and the reflective layer RFL. The protective layer PRL may be disposed on the second insulating layer INS2. In an embodiment, the protective layer PRL may be a single layer or multiple layers. In an embodiment, the protective layer PRL may be formed of the capping layer CPL or the overcoat layer OCL described in association with FIG. 29, or may include both the capping layer CPL and the overcoat layer OCL.

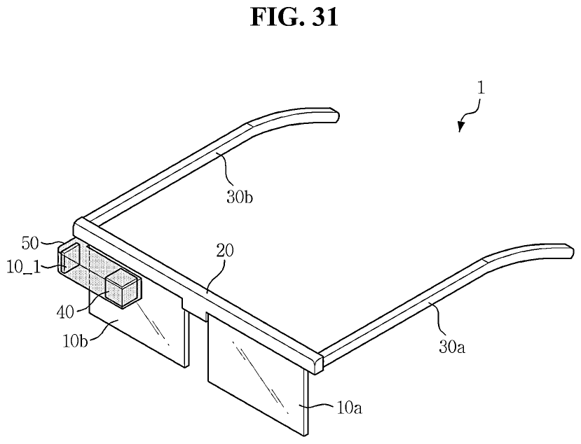

FIG. 31 is a diagram schematically illustrating a virtual reality device 1 including a display device 10_1 according to an embodiment.

Referring to FIG. 31, the virtual reality device 1 according to an embodiment may be a glasses-type device. The virtual reality device 1 according to an embodiment may include the display device 10_1, a left lens 10a, a right lens 10b, a support frame 20, temples 30a and 30b, a reflection member 40, and a display device housing 50.

Although FIG. 31 schematically illustrates the virtual reality device 1 including the temples 30a and 30b, embodiments are not limited to this example. For example, the virtual reality device 1 may be applied to (or as part of) a head mounted display including a head mounted band that may be worn on a head, instead of the temples 30a and 30b. The virtual reality device 1 according to some embodiments may be applied to (or as part of) other electronic devices in various forms.

The display device housing 50 may include the display device 10_1 and the reflection member 40. An image displayed on the display device 10_1 may be reflected by the reflection member 40 and provided to a user's right eye through the right lens 10b. Accordingly, the user can view the virtual reality image displayed on the display device 10_1 through the right eye.

Although FIG. 31 schematically illustrates the display device housing 50 being disposed at the right end of the support frame 20, embodiments are not limited to this example. For example, the display device housing 50 may be disposed at the left end of the support frame 20, and in some implementations, the image displayed on the display device 10_1 may be reflected by the reflection member 40 and provided to a user's left eye through the left lens 10a. Accordingly, the user can view the virtual reality image displayed on the display device 10_1 through the left eye. In some embodiments, the display device housing 50 may be disposed at both the left end and the right end of the support frame 20 or between the left end and the right end of the support frame 20. In this manner, the user may view the virtual reality image displayed on the display device 10_1 through both the left eye and the right eye.

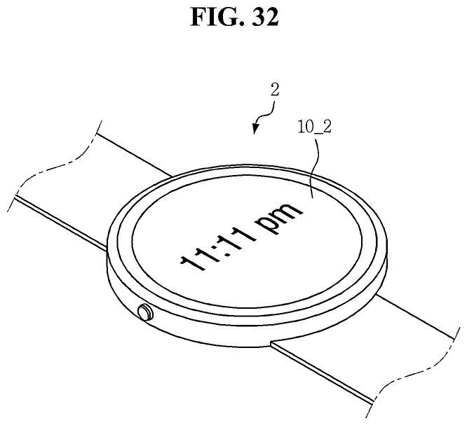

FIG. 32 is a diagram schematically illustrating a smart device including a display device 10_2 according to an embodiment.

Referring to FIG. 32, the display device 10_2 according to an embodiment may be applied to (or as part of) a smart watch 2 that is one of the smart devices. The planar shape of a clock display of the smart watch 2 may follow (or correspond with) the planar shape of the display device 10_2. For example, in a case that the display device 10_2 according to an embodiment has a planar shape, such as a circular planar shape or an elliptical planar shape, the clock display of the smart watch 2 may also have a corresponding planar shape, such as a corresponding circular planar shape or a corresponding elliptical planar shape. In a case that the display device 10_2 according to an embodiment has a quadrilateral planar shape, the clock display of the smart watch 2 may also have a corresponding quadrilateral planar shape. However, embodiments are not limited to these examples, and the clock display of the smart watch 2 may not follow (or correspond with) the planar shape of the display device 10_2.

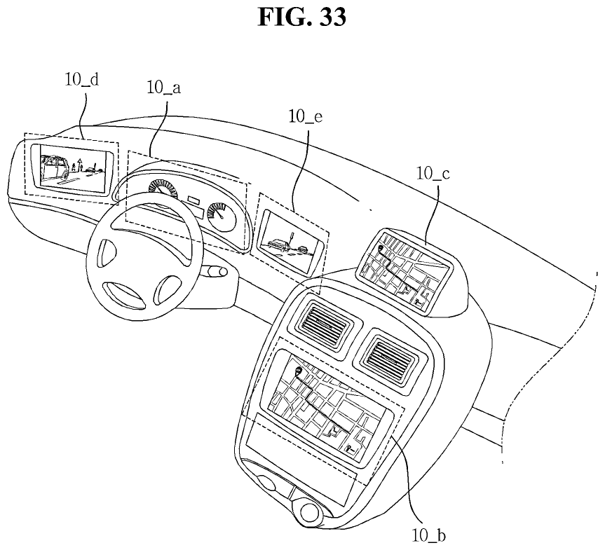

FIG. 33 schematically illustrates an automobile dashboard and center fascia including display devices 10_a, 10_b, 10_c, 10_d, and 10_e according to an embodiment. For instance, FIG. 33 schematically illustrates a vehicle to which the display devices 10_a, 10_b, 10_c, 10_d, and 10_e according to an embodiment are applied or used.

Referring to FIG. 33, the display devices 10_a, 10_b, and 10_c according to an embodiment may be applied to (or as part of) at least one of the dashboard of the automobile, the center fascia of the automobile, and the center information display (CID) of the dashboard of the automobile. In some implementations, the display devices 10_d and 10_e according to an embodiment may be applied to (or as part of) a room (or cockpit) mirror display instead of side mirrors of the automobile, the side mirrors being configured to provide respective external side views of the automobile and/or an external environment adjacent to the respective external sides of the automobile.

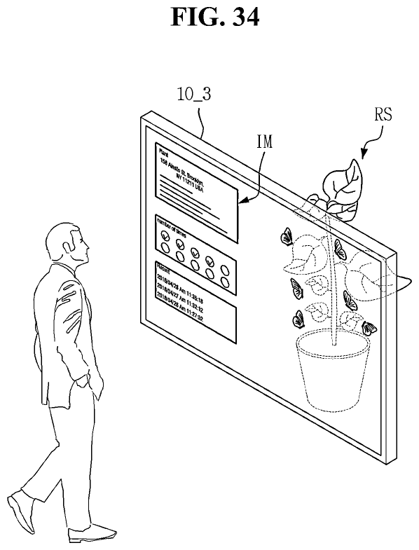

FIG. 34 is a diagram schematically illustrating a transparent display device including a display device 10_3 according to an embodiment.

Referring to FIG. 34, the display device 10_3 according to an embodiment may be applied to (or formed as part of) the transparent display device. The transparent display device may display an image IM, and may also transmit light. Accordingly, a user located in front of the transparent display device can view an object RS or a background located behind the transparent display device, as well as the image IM displayed on the display device 10_3. In a case that the display device 10_3 is applied to (or as part of) a transparent display device, the display panel 100 may include a light transmission portion configured to transmit light and/or may be formed on a substrate member made of a material configured to transmit light.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A light emitting element array comprising:
a substrate; and
light emitting elements disposed on the substrate, the light emitting elements comprising:
a first light emitting element configured to emit a first color of light; and
a second light emitting element configured to emit a second color of light different from the first color of light, wherein
each of the light emitting elements comprises:
a first semiconductor layer;
a second semiconductor layer disposed on the first semiconductor layer, the second semiconductor layer being doped to have a first conductivity type and containing indium;
a light emitting layer disposed on the second semiconductor layer, the light emitting layer containing indium; and
a third semiconductor layer disposed on the light emitting layer, the third semiconductor layer being doped to have a second conductivity type,
an indium content of the light emitting layer of the first light emitting element is higher than an indium content of the light emitting layer of the second light emitting element,
the second semiconductor layer of the first light emitting element is a multilayer structure, the multilayer structure comprising first layers containing indium and second layers alternately stacked with the first layers, and
the second semiconductor layer of the second light emitting element is a single layer structure containing indium.

2. The light emitting element array of claim 1, wherein
each of the first layers of the first light emitting element is an InGaN layer containing a dopant of the first conductivity type, and
each of the second layers of the first light emitting element is a GaN layer.

3. The light emitting element array of claim 2, wherein the second semiconductor layer of the second light emitting element is a single InGaN layer containing a dopant of the first conductivity type.

4. The light emitting element array of claim 2, wherein a thickness of each of the first layers of the first light emitting element is greater than a thickness of each of the second layers of the first light emitting element.

5. The light emitting element array of claim 4, wherein the thickness of each of the first layers of the first light emitting element is in a range of about 10 nm to about 20 nm.

6. The light emitting element array of claim 5, wherein the thickness of each of the second layers of the first light emitting element is less than or equal to about 5 nm and greater than 0 nm.

7. The light emitting element array of claim 1, wherein an indium content of at least one of the first layers of the first light emitting element is different from an indium content of at least one other first layer among the first layers of the first light emitting element.

8. The light emitting element array of claim 7, wherein
the second semiconductor layer of the first light emitting element comprises:
a first laminate comprising one or more first pairs of layers disposed on the first semiconductor layer, each of the one or more first pairs of layers comprising a first layer among the first layers and a second layer among the second layers;
a second laminate comprising one or more second pairs of layers disposed on the first laminate, each of the one or more second pairs of layers comprising a first layer among the first layers and a second layer among the second layers;
a third laminate comprising one or more third pairs of layers disposed on the second laminate, each of the one or more third pairs of layers comprising a first layer among the first layers and a second layer among the second layers; and
a fourth laminate comprising one or more fourth pairs of layers disposed on the third laminate, each of the one or more fourth pairs of layers comprising a first layer among the first layers and a second layer among the second layers, and
an indium content of those first layers of the second laminate and an indium content those first layers of the fourth laminate are at least about 5% lower than an indium content of those first layers of the first laminate and an indium content of those first layers of the third laminate.

9. The light emitting element array of claim 8, wherein both a number of the one or more first pairs of layers in the first laminate and a number of the one or more third pair of layers in the third laminate are greater than both a number of the one or more second pairs of layers in the second laminate and a number of the one or more fourth pairs of layers in the fourth laminate.

10. The light emitting element array of claim 1, wherein
the light emitting layer of the first light emitting element comprises a quantum well layer containing indium at a content in a range of about 30% to about 40%, and
an indium content of at least one of the first layers of the first light emitting element is less than or equal to about 30% and greater than 0%.

11. The light emitting element array of claim 1, wherein a peak wavelength of the second color of light is shorter than a peak wavelength of the first color of light.

12. The light emitting element array of claim 11, wherein
the emitting elements further comprise a third light emitting element configured to emit light of a third color, a peak wavelength of the third color of light being shorter than the peak wavelength of the second color of light, and
the second semiconductor layer of the third light emitting element is a single layer structure containing indium.

13. The light emitting element array of claim 1, further comprising:
an insulating layer disposed on a surface of the substrate,
wherein at least a portion of the insulating layer is disposed between the first light emitting element and the second light emitting element in a view in a direction perpendicular to the surface.

14. The light emitting element array of claim 13, wherein the insulating layer overlaps at least a portion of each of the light emitting elements, each of the portions comprising a peripheral side surface of a corresponding light emitting element among the light emitting elements.

15. The light emitting element array of claim 14, wherein a thickness of the insulating layer overlapping the at least the portion of the first light emitting element is different from a thickness of the insulating layer overlapping the at least the portion of the second light emitting element.

16. The light emitting element array of claim 14, further comprising:
a reflective layer disposed on the insulating layer,
wherein the reflective layer overlaps the peripheral side surfaces of the light emitting elements.

17. The light emitting element array of claim 1, wherein at least parts of the first semiconductor layers of the light emitting elements are integral with each other.

18. A display device comprising:
a first pixel comprising a first light emitting element configured to emit a first color of light; and
a second pixel comprising a second light emitting element configured to emit a second color of light, wherein
each of the first light emitting element and the second light emitting element comprises:
a first semiconductor layer;
a second semiconductor layer disposed on a surface of the first semiconductor layer, the second semiconductor layer being doped to have a first conductivity type and containing indium;
a light emitting layer disposed on a surface of the second semiconductor layer, the light emitting layer containing indium; and
a third semiconductor layer disposed on a surface of the light emitting layer, the third semiconductor layer being doped to have a second conductivity type,
an indium content of the light emitting layer of the first light emitting element is higher than an indium content of the light emitting layer of the second light emitting element,
the second semiconductor layer of the first light emitting element comprises first layers containing indium and second layers alternately stacked with the first layers, and
the second semiconductor layer of the second light emitting element is a single layer structure containing indium.

19. A method of manufacturing a light emitting element array, the method comprising:
forming a first semiconductor layer on a surface of a substrate;
forming, on the first semiconductor layer, a first mask layer comprising a first opening exposing a first area of the first semiconductor layer, the first mask layer overlapping both a second area and a third area of the first semiconductor layer in a direction perpendicular to the surface;
sequentially forming, on the first area, a second semiconductor layer doped to have a first conductivity type and containing indium, a light emitting layer containing indium, and a third semiconductor layer doped to have a second conductivity type;
forming, on the first mask layer, a second mask layer comprising a second opening exposing the second area, the second mask layer overlapping both the first area and the third area in the direction;
sequentially forming, on the second area, a second semiconductor layer doped to have the first conductivity type and containing indium, a light emitting layer containing indium, and a third semiconductor layer doped to have the second conductivity type;
forming, on the second mask layer, a third mask layer comprising a third opening exposing the third area, the third mask layer overlapping both the first area and the second area in the direction; and
sequentially forming, on the third area, a second semiconductor layer doped to have the first conductivity type and containing indium, a light emitting layer containing indium, and a third semiconductor layer doped to have the second conductivity type, wherein
an indium content of the light emitting layers formed in the first area, the second area, and the third area are different from each other, and
the second semiconductor layer formed on an area among the first area, the second area, and the third area where the light emitting layer having a highest indium content is also formed on has a multilayer structure, the multilayer structure comprising first layers containing indium and second layers alternately stacked with the first layers.

20. The method of claim 19, wherein each of the second semiconductor layers on an area among the first area, the second area, and the third area other than the area on which the light emitting layer having the highest indium content is formed is formed as a single layer structure.
